(19) United States
(12) Patent Application Publication
(10) Pub. No.: US 2025/0311150 A1
(43) Pub. Date: Oct. 2, 2025

(54) HEAT EXCHANGER PLATE AND ASSOCIATED USE AND ARRANGEMENT OF A TRACTION BATTERY ON A HEAT EXCHANGER PLATE

(71) Applicant: MAHLE International GmbH, Stuttgart (DE)

(72) Inventors: Jens Richter, Grossbottwar (DE); Ulrich Maucher, Korntal-Münchingen (DE); Nicolas Ferrand, Stuttgart (DE)

(21) Appl. No.: 18/963,476

(22) Filed: Nov. 27, 2024

(30) Foreign Application Priority Data
Mar. 28, 2024 (DE) 10 2024 109 025.1

(51) Int. Cl. H05K 7/20; B60L 58/26

(52) U.S. Cl. CPC H05K 7/20254; B60L 58/26; H05K 7/20272

(57) ABSTRACT

A heat exchanger plate for temperature control of an electric component via a liquid temperature control agent may include a plate body having a temperature control zone including a duct system fluidically connecting an intake line to a discharge line. The duct system may have a left and a right minimum distance extending along a left and a right duct boundary contour, respectively, from the intake line to the discharge line. A total duct system length may be 50% or less greater than a longer of the left and right minimum distance. The duct system may have an entry region, an exit region, and a connecting region extending therebetween. A length of the entry and/or exit region may be 20% to 40% of the total duct system length. A mean entry region cross-section in the entry region may be larger than a mean exit region cross-section in the exit region.

### CROSS-REFERENCE TO RELATED APPLICATIONS

This application claims priority to German Patent Application No. DE 10 2024 109 025.1, filed on Mar. 28, 2024, the contents of which is hereby incorporated by reference in its entirety.

### TECHNICAL FIELD

The present invention relates to a heat exchanger plate for temperature control of at least one electric and/or electronic component by means of a liquid temperature control agent. The invention also relates to a use of such a heat exchanger plate. Furthermore, the invention relates to an arrangement of a traction battery on such a heat exchanger plate.

### BACKGROUND

In a variety of technical applications, heat must be dissipated from electrical components to prevent them from overheating and to slow down the aging process. Similarly, it may be necessary to heat certain electrical components and/or in certain operating conditions, for example to achieve a particularly high level of efficiency. For example, in the case of a traction battery for a battery-powered electric vehicle, it can be advantageous for an optimized charging process to heat the battery cells of the traction battery to a charging temperature. Even while the traction battery is supplying power, it may be necessary, for example at low ambient temperatures, to warm the battery cells to prevent premature discharge. By contrast, when batteries are delivering high power, it may be necessary to cool them to prevent the battery cells from overheating and also to improve energy efficiency.

For temperature control, i.e. for heating or cooling, heat exchanger plates can be used through which a liquid temperature control agent can flow and which, when used, are in heat-transferring contact with the respective component to be temperature-controlled, in particular with a traction battery. These heat exchanger plates are characterized by their flat and particularly even design and require little installation space. For example, such heat exchanger plates can be accommodated in a battery casing to hold battery cells.

In the event that a large number of electrical or electronic components or a correspondingly large electrical component, such as a traction battery, is to be temperature controlled as uniformly as possible, a heat exchanger plate, which has an intake line for supplying the temperature control agent and a discharge line for discharging the temperature control agent, often has the problem that in a duct system that carries the temperature control agent which is formed in the interior of the heat exchanger plate and fluidically connects the intake line to the discharge line, the heat is not supplied uniformly to the respective component or is not uniformly removed from it, for example because the temperature of the temperature control agent inevitably decreases or increases from the intake line to the discharge line along the cooling duct system, depending on whether heat is to be supplied or removed.

### SUMMARY

The present invention addresses the problem of specifying an improved design for a heat exchanger plate of the type described above, or for an associated application, which is characterized in particular by a heat transfer performance that is as homogeneous as possible along the heat exchanger plate.

According to the invention, this problem is solved by the subject-matter of the independent claim(s). Advantageous embodiments are the subject-matter of the dependent claim(s).

The invention is based on the general idea of configuring the duct system, which is formed in the interior of a plate body of the heat exchanger plate, according to a first aspect such that a cross-section of the duct system through which flow is possible is larger in an entry region on the intake line side than in an exit region on the discharge line side, and, according to a second aspect, to be configured such that a mean flow path in the duct system is at most 50%, preferably at most 25%, greater than a minimum path or minimum distance that the temperature control agent must flow along an edge of the duct system from the intake line to the discharge line. Due to the first aspect, the temperature control agent inevitably flows faster in the exit region than in the entry region when the heat exchanger plate is in operation. However, the flow rate of the temperature control agent correlates with the heat transfer rate, so that the heat transfer improves with increasing flow rate. During operation of the heat exchanger plate, heat transfer has already taken place in the entry region, so that the temperature difference between the temperature control agent and the respective region of the heat exchanger plate is reduced in the exit region. To homogenize the heat transfer performance along the duct system, the reduced temperature difference in the exit region can be largely compensated by the higher flow velocity in the exit region. The company's research has shown that the second aspect significantly improves the effect of the first aspect, thereby contributing to the homogenization of the heat transfer performance along the heat exchanger plate. A pressure drop occurs in the temperature control agent along the flow path. In a narrow duct cross-section, the increased flow velocity then leads to a very sharp increase in pressure loss. By combining the largest possible duct cross-section with the shortest possible ducts, a very large region of the heat exchanger plate can be cooled in regions with lower cooling requirements, with minimized pressure loss and thus minimal pump power to drive the temperature control agent. The second aspect of the maximum flow path length thus leads to an optimization of pressure loss and an increase in the efficiency of the heat exchanger plate. This optimization or increase in efficiency works better the smaller the ratio of the mean flow path length to the path length of the larger minimum path.

In the present context, the term “configuration” is synonymous with the term “arrangement” so that the phrase “configured in such a way that” is synonymous with the phrase “arranged in such a way that”.

Specifically, the duct system defines a main flow direction for the temperature control agent flowing in the duct system from the intake line to the discharge line, wherein the duct system has a left duct boundary contour and a right duct boundary contour with respect to the main flow direction, which delimit a cross-section of the duct system available to the temperature control agent for flow through, transverse to the main flow direction. The duct system also defines a minimum distance on the left, which leads from the intake line along the left duct boundary contour to the discharge line, and a minimum distance on the right, which leads from the intake line along the right duct boundary contour to the discharge line. The duct system has a total duct system length leading from the intake line to the discharge line. According to the invention, the duct system is configured in such a way that the total duct system length is at most 50%, in particular at most 25%, greater than the larger of the left and right minimum distances, or at most 50%, in particular at most 25%, greater than the left or right minimum distance if the left minimum distance and the right minimum distance are the same size. Furthermore, the duct system has an entry region with an entry region length that extends over 20% to 40% and preferably over 25% to 35% of the total duct system length. In addition, the duct system has an exit region which has an exit region length extending over 20% to 40%, and preferably over 25% to 35%, of the total duct system length. A connecting region of the duct system connects the entry region with the exit region. According to the invention, the duct system is now configured such that a mean entry region cross-section available to the temperature control agent in the entry region for flow is larger than a mean exit region cross-section available to the temperature control agent in the exit region for flow.

The intake line has at least one intake line connection for connecting an intake line to supply the temperature control agent. Typically, the intake line has only one intake line connection. However, it may be advantageous to provide two or more separate intake line connections, which then jointly form the intake line.

The discharge line includes at least one discharge line connection for connecting a discharge line to remove the temperature control agent. Usually, the discharge line has only one discharge line connection. However, it may be advantageous to provide two or more separate discharge line connections, which then jointly form the discharge line.

Investigations by the applicant have shown that the heat transfer capacity along the heat exchanger plate can be distributed all the more homogeneously over the entire temperature-controlled region of the heat exchanger plate, the smaller the ratio of the total duct system length to the larger of the left and right minimum distances, if these are of different lengths or sizes, or of the total duct system length to the left or right minimum distances, if these are of the same size or length. Accordingly, according to advantageous embodiments, it may be provided that the duct system is configured such that the total duct system length is at most 40% or at most 30% or at most 25% or at most 20% or at most 15% or at most 10% or at most 5% greater than or, in particular, at most equal to the larger of the left and right minimum distance if the left minimum distance and the right minimum distance are not the same size, or at most 40% or at most 30% or at most 25% or at most 20% or at most 15% or at most 10% or at most 5% greater than or in particular at most equal to the left or right minimum distance if the left minimum distance and the right minimum distance are the same size. Consequently, a particularly favorable configuration can result if the total duct system length is smaller than the larger of the left and right minimum distances or smaller than the left or right minimum distance if the left and right minimum distances are the same size.

According to a favorable embodiment, it may now be provided that the duct system has a distributing region having the intake line, which has a distributing region length, that the duct system has a collecting region having the discharge line, which has a collecting region length. Furthermore, the duct system can form a contact region within the temperature control zone, which is configured on the plate surface for heat-transferring coupling with the respective component to be temperature-controlled and has a contact region length that extends from the distributing region to the collecting region, wherein the entry region extends within the contact region and adjoins the distributing region, wherein the exit region extends within the contact region and adjoins the collecting region. This means that the distributing region with the intake line and the collecting region with the discharge line are excluded from the above design criteria for the distribution of the total duct system length over the region lengths, so that the design can be realized more precisely. In particular, with this configuration, the contact region can be used by the respective component to be cooled due to the intended contact or assignment, so that the heat exchanger plate can be customized with regard to the actual temperature control conditions.

In particular, it may be stipulated that the entry region length, the exit region length and the connecting region length each amount to ⅓ of the contact region length. This results in a significant simplification of the design.

A configuration is advantageous in which the distributing region length and the collecting region length each amount to a maximum of 15%, or preferably a maximum of 10%, of the total duct system length. This design criterion provides an indirect definition of the contact region.

In another embodiment, it may be provided that the distributing region length and the collecting region length each amount to 9.5% or together 19% of the total duct system length, wherein it is also provided that the entry region length, the exit region length and the connecting region length each amount to 27% or together 81% of the total duct system length. In this configuration, the contact region can also be defined indirectly.

According to a favorable embodiment, it may be provided that in the duct system, in the main flow direction, a distance between the left and right duct boundary contour varies. The duct system can have at least one duct section between the intake line and discharge line, which extends in the main flow direction from one extremum of the distance to the next following extremum of the distance. The respective extremum can be a maximum or a minimum. The two extrema are a minimum and a maximum, so that the respective duct section extends from a minimum to a maximum or from a maximum to a minimum. In a duct section where the distance between the left and right duct boundary contour is constant, this duct section extends along the extremum, which can be a minimum or a maximum, so that there can be a maximum or a minimum at the beginning and at the end of such a duct section, forming the transition to the adjacent duct section. In such a duct section, the distance forms a plateau. The respective extremum is defined by the fact that a straight line running along the distance is perpendicular to the left duct boundary contour and perpendicular to the right duct boundary contour at the respective extremum. The respective duct section has a section length measured along a centerline of the duct section. The centerline is formed by the midpoints of connecting straight lines, each of which connects a point of the left duct boundary contour, which has a percentage of length portion between the two extrema on the left duct boundary contour lying in the range from 0% to 100%, with a point of the right duct boundary contour, which has the same percentage of length portion between the extrema on the right duct boundary contour. For example, such a connecting straight line connects a point that lies at n %, e.g. at 10%, of the length of the left duct boundary contour, with a point that lies at n %, e.g. at 10%, of the length of the right duct boundary contour. The geometric center of this connecting straight line then forms a point along the centerline. At 0%, the connecting straight line corresponds to the extremum at the beginning of the duct section and at 100%, the connecting straight line corresponds to the extremum at the end of the duct section. This precisely defines the section length. The total duct system length is now formed by the sum of the lengths of all the successive duct sections from the intake line to the discharge line. This exactly defines the total duct system length. For an intake line with only one intake line connection, the geometric center of the intake line connection is used as the starting point of the centerline. For an intake line with multiple intake line connections, the geometric center of an envelope that envelops the intake line connections, the so-called “envelope”, is used as the starting point of the centerline. For a discharge line with only one discharge line connection, the geometric center of the discharge line connection is used as the end point of the centerline. For a discharge line with multiple discharge line connections, the geometric center of an envelope that envelops the discharge line connections, the so-called “envelope”, is used as the end point of the centerline. The duct system can be configured to have only a single duct section. Usually, however, the duct system has several duct sections that immediately follow one another in the flow direction of the temperature control agent. In two consecutive duct sections, which form an upstream duct section and a downstream duct section, where the temperature control agent first flows through the upstream duct section during operation of the heat exchanger plate, and then flows through the downstream duct section, the extremum at the end of the upstream duct section simultaneously forms the extremum at the beginning of the downstream duct section. In other words, the respective extremum forms the transition between two adjacent duct sections. In the case of the heat exchanger plate that has just been configured, the heat exchanger plate defines a plate plane and the distances, extrema, straight lines and connecting straight lines mentioned above extend parallel to the plate plane. In particular, the distances, extrema, straight lines and connecting straight lines mentioned lie in a plane parallel to the plate plane.

The distance can be measured on the left and right duct boundary contour with respect to the height direction, preferably in the center of a region with the largest inclination angle with respect to the plate plane. For straight duct boundary contours, the inclination to the plate plane is constant along the duct boundary contour, so that the distance measurement with respect to the height direction is taken in the center of the respective duct boundary contour. For curved duct boundary contours, the steepest point of the duct boundary contour is used for distance measurement. If this steepest point is a point on the respective duct boundary contour, the distance measurement is taken in relation to the height direction at this point. If this steepest point is a straight region of the respective duct boundary contour with a constant inclination, the distance measurement in the vertical direction is taken in the center of this straight region.

According to a favorable embodiment, it may be provided that the mean entry region cross-section is formed by an entry region volume, relative to the entry region length, available to the temperature control agent in the entry region for flow through, and/or that the mean exit region cross-section is formed by an exit region volume, relative to the exit region length, available to the temperature control agent in the exit region for flow through. By relativizing the volume using the length, an averaged cross-section that can be flowed through is provided, which simplifies a comparison of the cross-sections that can be flowed through in the entry region and exit regions.

According to a favorable embodiment, it may be provided that the entry region length is formed by the sum of the section lengths of all the duct sections lying in the entry region. Additionally or alternatively, it may be provided that the exit region length is formed by the sum of the section lengths of all duct sections lying in the exit region. This makes it possible to determine the length of the entry and exit regions easily and accurately.

According to a favorable embodiment, it may be provided that the mean entry region cross-section is at least 50% larger than the mean exit region cross-section. The notifying party's investigations have shown that this improves the homogenization of the heat transfer.

It is advisable for the mean cross-section through which flow can occur in the entry region to increase from the intake line to the connecting region. In the exit region, the cross-section that can be flowed through can preferably decrease from the connecting region to the outlet connection. The cross-section available for flow can also preferably decrease within the connecting region from the entry-side transition to the exit-side transition.

The duct system extends in a temperature control zone within the plate body. The invention is based on a heat exchanger plate for temperature controlling at least one electric and/or electronic component by means of a liquid temperature control agent, which has a plate body that has a plate surface for heat-transferring coupling with the respective component to be temperature controlled and a peripheral plate edge. The plate body has at least one temperature control zone within the plate edge, which zone has an intake line formed on the plate body with at least one intake line connection for supplying the temperature control agent, a discharge line formed on the plate body with at least one discharge line connection for discharging the temperature control agent, and a duct system formed in the plate body for conducting the temperature control agent, which fluidically connects the intake line to the discharge line.

According to a favorable embodiment, it can be provided that the mean entry region cross-section is in a range from 70% to 600%, preferably in a range from 100% to 400%, of the mean exit region cross-section, in each case including the region boundaries. It has been shown that a particularly homogeneous heat transfer can be achieved in these regions over the total duct system length.

According to a favorable embodiment, it may be provided that a mean cross-section of the connecting region available for the temperature control agent to flow through in the connecting region is smaller than the mean entry region cross-section and larger than the mean exit region cross-section. The idea of a decreasing cross-section to increase the flow rate and improve heat transfer is consistently implemented here, even in the connecting region.

According to a favorable embodiment, the mean cross-section of the connecting region can be formed by a connecting region volume, which is available to the temperature control agent in the connecting region for the flow, relative to a connecting region length, which extends from the entry region to the exit region. The length-related volume provides a cross-section that is easy to compare.

According to a favorable embodiment, it may be provided that the connecting region length is formed by the sum of the section lengths of all the duct sections lying in the connecting region. This also makes it easier to determine the length of the connecting region precisely.

According to a favorable embodiment, the duct system can be configured such that it has a smaller heat transfer coefficient in the entry region than in the exit region and/or in the connecting region. This allows the larger volume flow rate in the entry region to be compensated for in order to homogenize the heat transfer performance.

According to a favorable embodiment, the duct system can be provided with several ducts through which the temperature control agent can flow in parallel in the entry region and/or exit region. The number of such ducts makes it particularly easy to vary the cross-section intended for the flow. A configuration in which the number of ducts in the exit region is between 20% and 70% of the number of ducts in the entry region is advantageous. In other words, there are fewer ducts in the exit region than in the entry region. In particular, collecting ducts are located in the exit region, while distributing ducts can be found in the entry region, along with connecting ducts at least in some cases. These collecting ducts, distributing ducts and connecting ducts will be explained in more detail below.

According to a preferred embodiment, the respective duct system can be equipped with several distributing ducts, several connecting ducts and several collecting ducts, wherein the distributing ducts are fluidically connected to the intake line and branch off into the connecting ducts, while the connecting ducts open into the collecting ducts and the collecting ducts are fluidically connected to the discharge line. Furthermore, an outer distributing duct and an outer collecting duct are defined in the duct system, which are connected to one another by several connecting ducts and are arranged comparatively close to a zone edge of the respective temperature control zone or to a plate edge of the plate body. The latter can be the case in particular when the zone edge coincides with the plate edge, preferably when the plate body has only a single temperature control zone. In addition, the duct system is used to form at least one inner distributing duct and at least one inner collecting duct, which are connected to one another via a plurality of connecting ducts and which are further away from the zone edge and the plate edge, respectively, than the outer distributing duct and the inner distributing duct. This design ensures a uniform flow through an outer zone section or plate section, which is adjacent to the zone edge or plate edge and in which the outer distributing duct and the outer collecting duct as well as the associated connecting ducts, and an inner plate section, which is arranged further away from the zone edge or plate edge and in which the inner distributing duct, the inner collecting duct and the associated connecting ducts run. It may also be useful to ensure that the inner collecting duct and the outer collecting duct have approximately the same duct length with regard to the flow direction of the temperature control agent. This means that a pressure drop in the inner collecting duct that correlates with the duct length can be dimensioned to be largely the same as in the outer collecting duct. This also allows an approximately equal temperature change to be realized in the inner collecting duct and in the outer collecting duct. This measure significantly supports a uniform flow through the ducts in the inner and outer plate sections, which in turn supports homogeneous temperature control.

In detail, the duct system can have at least two distributing ducts for this purpose, which are fluidically connected to the intake line and which each branch into several straight connecting ducts, through which the temperature control agent flows in parallel and which, in particular, can run parallel to one another. Furthermore, the duct system has at least two collecting ducts that are fluidically connected to the discharge line and into each of which several of the connecting ducts open.

The effective length of a straight duct section can be defined as the distance from the inlet to the outlet of the straight duct section. In the case of a duct section corrugated transverse to a main flow direction, the effective length can be formed by the distance measured in the main flow direction from the inlet to the outlet of the duct section corrugated transverse to the main flow direction. In the case of a loop-shaped or loop-like duct section, which has three straight duct sections and two duct sections bent through 180°, each of which connects two of the straight duct sections to one another, the effective length can be formed by the distance from the inlet of the first straight duct section, which is connected to the second straight duct section via the first bent duct section, to the outlet of the third straight duct section, which is connected to the second straight duct section via the second bent duct section.

A relatively long duct length from the entry of one straight duct section to the exit of the other straight duct section can result from a loop-shaped or curved duct section that has two straight duct sections and a 180° bent duct section that connects the two straight duct sections. Such longitudinal loops or loops can be used in conventional duct systems to equalize the length between internal path and external paths. In particular, it allows very long paths to be realized. These large path lengths also increase the mean flow path of the duct system and the total duct system length, so that the mean flow path or the total duct system length can be slightly more than 50% greater than the larger of the two minimum paths or minimum distances, in particular when such a longitudinal loop is arranged between the two duct boundary contours so that it does not increase the associated minimum distance at the respective duct boundary contour. In the case of the heat exchanger plate according to the invention, there is no need for such long loop-shaped or bow-shaped paths, as the requirement that the mean flow path or the total duct system length must be a maximum of 50% larger than the larger minimum path or minimum distance.

Since the same performance can be achieved with deep contoured ducts with lower pressure loss as in shallower non-contoured ducts, the preferred method of reducing the cross-section towards the exit is to reduce the number of parallel ducts or to reduce the width of the ducts. Both of these factors lead to a reduction in the overall width of the region of the plate surface that is washed out by parallel ducts. To achieve particularly high-performance ducts, however, it can also be useful to reduce the duct height in regions with increased heat transfer requirements in order to achieve an additional reduction in the total cross-section that can be flowed through.

The cross-section of the respective duct through which air can flow is essentially determined by the duct height measured perpendicular to the plate plane and the duct width measured perpendicular to the duct height. The cross-section to be considered extends perpendicular to a neutral fiber or centerline of the respective duct. For a duct with essentially straight lateral duct boundaries, the centerline corresponds to the center between the lateral duct boundaries. However, if the sides of the duct are not straight, determining the centerline and thus the cross-section to be considered is comparatively complex. In principle, flow simulations can be used to determine the centerline and thus the cross-section to be considered for the flow.

According to a favorable embodiment, the duct system can have an external path that is formed by one of the distributing ducts, one of the connecting ducts and one of the collecting ducts and extends along a zone edge of the temperature control zone, wherein the external path is at most 30% longer than a shortest connecting path leading from the intake line to the zone edge, along the zone edge and along the external path, and from the zone edge to the discharge line. Typically, such an outer path can form the longest path within the respective temperature control zone. The measure presented here ensures that this longest path is designed to be as short as possible, namely a maximum of 30% longer than the shortest possible path along the zone edge to connect the intake line with the discharge line. This simplifies the alignment of all other paths with the outer path in terms of heat transfer performance, which favors the desired homogenization.

The duct system can have several paths, each of which guides the temperature control agent from the intake line through one of the distributing ducts, one of the connecting ducts and one of the collecting ducts to the discharge line and each of which has a path length. These paths can have different lengths. The path with the largest path length defines the longest path. In another advantageous embodiment, it may be provided that each path whose path length is less than 50%, in particular less than 60%, preferably less than 75%, of the path length of the longest path, forms a short path. A configuration is preferred in which the sum of the smallest cross-sections through which flow is possible in all short paths is less than 40%, in particular less than 20%, preferably less than 10%, of the sum of the cross-sections through which flow is possible in all other paths. It is necessary to assume that “all other paths” include at least the longest path and—if available—every other path whose path length is greater than 50%, in particular greater than 60%, preferably greater than 75%, the path length of the longest path. These other paths can also be seen as long paths. If two or more paths exist with the same path length, but one of them is longer or greater than the path length of all the other paths, then one of these paths can form the longest path, while the other path or paths then form a long path or one of the other paths respectively.

The distributing ducts can be designed such that they form at least one inner distributing duct and one outer distributing duct, wherein the outer distributing duct runs directly adjacent to the zone edge or the plate edge and thus runs closer to the zone edge or plate edge than the respective inner distributing duct, in particular than the inner distributing duct directly adjacent to the outer distributing duct. Analogously to this, the collecting ducts form at least one inner collecting duct and one outer collecting duct, wherein the outer collecting duct runs directly adjacent to the zone edge or plate edge and thus runs closer to the zone edge or plate edge than the respective inner collecting duct, in particular than the inner collecting duct directly adjacent to the outer collecting duct. At least two connecting ducts branch off from the outer distributing duct and flow into the outer collecting duct. At least two connecting ducts branch off from the inner distributing duct and open into the inner collecting duct. This measure simplifies the homogenization of the duct system over the surface of the respective temperature control zone.

The inner collecting duct has a duct length in one flow direction of the temperature control agent. The outer collecting duct has a duct length in the flow direction of the temperature control agent. It may be expedient to ensure that the inner collecting duct and the outer collecting duct in the plate body are configured in such a way that the duct length of the inner collecting duct is at least 75% of the duct length of the outer collecting duct. This means that the inner collecting duct is not or not much shorter than the outer collecting duct, which favors the desired homogenization of the heat transfer performance.

An advantageous embodiment is one in which the length of the duct of the inner collecting duct is at least 80%, preferably at least 85%, in particular at least 90%, of the length of the duct of the outer collecting duct. Thus, the inner collecting duct and the outer collecting duct have essentially the same duct length.

The optional parallel alignment of the connecting ducts enables a largely homogeneous temperature control of the affected region of the plate body.

An embodiment is preferred in which the inner collecting duct, in particular in contrast to the outer collecting duct, has a loop section and/or a meandering section for increasing the duct length of the inner collecting duct. Since the inner collecting duct inside the plate body is further away from the plate edge, it cannot achieve the same length as the outer collecting duct by means of straight duct sections. This can be compensated for by integrating a meandering section or a loop section. A loop section represents a detour compared to a direct or straight connection. A loop section can have three straight longitudinal sections and two bent sections. The three longitudinal sections form a first, a second and a third longitudinal section, run parallel to each other and are arranged next to each other at right angles to their longitudinal direction. The two bent sections form a first and second bent section and each create a 180° flow diversion. The first longitudinal section has an inlet for the loop section and is connected to the second longitudinal section by the first bent section. The second longitudinal section is connected to the third longitudinal section by the second bent section. The third longitudinal section has an outlet of the loop section. Alternatively, a loop section can be configured to have two straight duct sections, one 180°-bent duct section, and two 90°-bent duct sections. The 180° bent section connects the two straight duct sections. The 90° bent section connects one inlet of the loop section to the first straight duct section. The other 90° bent section connects the second straight duct section with an outlet of the loop section.

A meandering section represents at least four immediately successive elbow sections that form a 90° bent section with an inlet of the meandering section, a 90° elbow with an outlet of the meandering section, and two or more 180° elbows that connect the inlet-side 90° elbow to the outlet-side 90° elbow.

According to another embodiment, the inner collecting duct and the outer collecting duct can each have at least two longitudinal sections in which the inner collecting duct and the outer collecting duct run parallel to adjacent longitudinal sections of the zone edge and the plate edge, respectively. This ensures that the temperature control of the plate body is as uniform and homogeneous as possible along the plate edge.

In another embodiment, it may be provided that at least one connecting duct branching off from the inner distributing duct opens into the outer collecting duct. Alternatively, it may also be provided that at least one connecting duct branching off from the outer distributing duct opens into the inner collecting duct. This further improves the homogenization of the temperature control. It is clear that in such an embodiment, at least one of the two distributing ducts branches into at least three connecting ducts.

It is advantageous if the connecting ducts run largely parallel to a longitudinal section of the zone edge or the plate edge. The parallel alignment of the connecting ducts to a longitudinal section of the zone edge or plate edge results in a particularly compact design for the heat exchanger plate and a homogeneous temperature distribution up to the zone edge or plate edge.

The heat exchanger plate or its plate body extends in a plate plane. Preferably, the heat exchanger plate or its plate body has a rectangular cross-section in the plate plane. Accordingly, the plate edge has two longer rectilinear longitudinal sections and two shorter rectilinear longitudinal sections.

In another advantageous embodiment, the inner collecting duct and the outer collecting duct can each have a longitudinal section that runs parallel to the connecting ducts. This also supports a compact design of the heat exchanger plate, wherein a comparatively large volume is provided within the plate body for the ducts of the duct system.

According to a particularly advantageous embodiment, the ducts in the exit region and/or the collecting ducts can be provided with a larger heat transfer coefficient than the ducts in the entry region and/or the distributing ducts and/or the connecting ducts. These designs are based on the consideration that the heat transfer performance depends, on the one hand, on the temperature difference between the temperature control agent and the plate body and, on the other hand, on the heat transfer coefficient between the temperature control agent and the plate body. The temperature difference between the temperature control agent and the plate body inevitably decreases in the duct system on the way from the intake line to the discharge line. The increase in the heat transfer coefficient in the region of the collecting ducts can compensate for this, in order to homogenize the heat transfer over the entire heat exchanger plate. The heat transfer coefficient takes into account parameters that are responsible for the heat transfer between the temperature control agent and the plate body, except for the composition of the temperature control agent and the temperature difference between the temperature control agent and the plate body. Parameters that can be taken into account in the heat transfer coefficient are, for example, the actual flow rate of the temperature control agent in the respective duct and/or the nature of the flow of the temperature control agent in the respective duct, for example, the flow may be laminar or more or less turbulent, and/or the surface available for heat transfer that comes into contact with the temperature control agent, and/or the pressure in the temperature control agent. Another parameter that can be taken into account in the heat transfer coefficient is the thermal conductivity of the materials involved. Since the material of the plate body is functionally the same for all ducts, such material differences can play a role, for example, in heat-conducting elements that can be inserted into the ducts or formed therein.

By increasing the heat transfer coefficient in the region of the collecting ducts compared to the connecting ducts, a reduced temperature of the temperature control agent in the collecting ducts compared to the connecting ducts can be compensated for, so that ultimately the same heat transfer performance can be achieved in the region of the connecting ducts on the one hand and in the region of the collecting ducts on the other. In this design, heat transfer in the region of the connecting ducts is mainly based on the higher temperature difference between the temperature control agent and the plate body. In contrast to this, heat transfer in the region of the collecting ducts occurs mainly on the basis of the increased heat transfer coefficient.

It is acceptable for the cross-section of the respective collecting duct through which flow can occur to be smaller than the sum of the cross-sections of the connecting ducts through which flow can occur that open into it. This ensures that the flow velocity in the collecting ducts is higher than in the connecting ducts. This also increases the pressure of the temperature control agent inside the collecting ducts. These measures improve heat transfer in the region of the collecting ducts.

Another embodiment proposes that the flow resistance in the respective collecting duct is greater than in the connecting ducts that open into it. The higher flow resistance changes the flow of the temperature control agent. On the one hand, this increases the pressure in the temperature control agent. On the other hand, turbulence in the flow can also increase. These measures improve heat transfer in the region of the collecting ducts.

According to another embodiment, heat-conducting elements can be provided in the collecting ducts, in particular in contrast to the connecting ducts opening into them, which improve the heat transfer between the temperature control agent and the plate body. These measures improve heat transfer in the region of the collecting ducts.

In accordance with a favorable embodiment, if heat-conducting elements are arranged in both the collecting ducts and the connecting ducts, the heat-conducting elements arranged in the collecting ducts can have a larger number and/or a larger arrangement density and/or a larger surface area exposed to the temperature control agent and/or a larger heat conductivity than the heat-conducting elements arranged in the connecting ducts. These measures also support heat transfer in the collecting ducts, both individually and cumulatively, and in any combination.

In particular, it may be required that a number of connecting ducts is at least twice as large as or more than twice as large as a number of collecting ducts. For example, a configuration is conceivable in which six connecting ducts and only two collecting ducts are provided. Another possible configuration would be to plan for eight connecting ducts and three collecting ducts.

In another embodiment, the intake line and discharge line on the plate body can be arranged next to each other at the same end section of the plate body, preferably at one longitudinal end of the plate body. This achieves a U-configuration for the duct system within the associated temperature control zone. The outer distributing duct, the connecting duct directly adjacent to the edge of the plate and the outer collecting duct in the duct system can advantageously form an edge duct running around the plate edge, which fluidically connects the intake line to the discharge line and extends along the plate edge. This helps to ensure a homogeneous distribution of the heat transfer performance along the plate body. Alternatively, an embodiment is also conceivable in which the intake line and discharge line are located at opposite longitudinal ends of the plate body.

In an alternative embodiment, the intake line and discharge line can be arranged on the plate body at opposite end sections of the plate body. This achieves an I-configuration for the duct system within the associated temperature control zone. This favors a symmetrical structure of the duct system.

In another embodiment, the duct system can be formed by a single meandering duct that connects the intake line to the discharge line. This also favors a simple structure.

One embodiment in which the duct has a multiplicity of separate, dissimilar and asymmetrically distributed contours for flow control and heat transfer, around which the temperature control agent can flow, is particularly advantageous. In particular, a configuration can be achieved that is also disclosed in DE 10 2023 118 768, the contents of which is hereby incorporated by reference in its entirety.

In another embodiment, the contours formed in the exit region may differ from the contours arranged in the entry region in terms of a greater arrangement density and/or smaller distances from one another and/or smaller dimensions. This can help to achieve the desired homogenization.

According to a particularly advantageous embodiment, the plate body can be provided with at least two such temperature control zones within the plate edge, each of which has an intake line, formed on the plate body, for supplying the temperature control agent, a discharge line, formed on the plate body, for draining the temperature control agent, and a duct system, formed in the plate body, for conducting the temperature control agent, which fluidically connects the intake line to the discharge line. Thus, the plate body has at least two separate intake lines, at least two separate discharge lines and at least two separate duct systems. It may be expedient to provide that at least two of the temperature control zones are identical or mirror-symmetrical or differently designed with regard to the respective intake line, discharge line and duct system.

Likewise, a configuration is advantageous in which the plate body has only a single temperature control zone. In particular, the zone edge can then coincide with the plate edge.

An application of a heat exchanger plate according to the invention, as described above, is characterized by the fact that the heat exchanger plate is used for temperature controlling battery cells of a traction battery of a battery-powered electric vehicle. With the help of the heat exchanger plate presented here, a comparatively large number of individual battery cells can be temperature controlled to a large extent uniformly, so that overheating or undercooling of individual battery cells within the traction battery can be avoided.

An arrangement of a traction battery on a heat exchanger plate of the type described above, according to the invention, is characterized in that the traction battery is arranged within the contact region on the plate surface and is coupled to the heat exchanger plate in a heat-transferring manner. In particular, the dimensions of the traction battery define the extent of the contact region within the duct system. In other words, the distributing region and the collecting region are both outside the traction battery, while the contact region is covered by the traction battery.

The arrangement of the traction battery on the heat exchanger plate corresponds to a unit consisting of the traction battery and the heat exchanger plate, in which the traction battery is arranged within the contact region on the plate surface and coupled to the heat exchanger plate in a heat-transferring manner.

The traction battery can be arranged directly on the heat exchanger plate as a uniform assembly. The traction battery usually has a large number of battery cells. In principle, the battery cells can be arranged directly on the heat exchanger plate. It is also conceivable that the traction battery has several battery modules, each of which has several battery cells. In this case, the battery modules can be arranged directly on the heat exchanger plate.

Further important features and advantages of the invention are apparent from the sub-claims, from the drawings, and from the associated description of the figures with reference to the drawings.

It is understood that the above-mentioned features and those yet to be explained below can be used not only in the combination indicated in each case, but also in other combinations or on their own, without deviating from the scope of the invention defined by the claims. The components of a superordinate unit, such as a device, an apparatus, or an arrangement, which are described separately, having been mentioned above or to be mentioned below, can represent separate components of this unit or can form integral regions or sections of this unit, even if this is shown differently in the drawings.

Preferred exemplary embodiments of the invention are shown in the drawings by way of example and will be explained in more detail in the following description, wherein identical reference numbers refer to identical or similar or functionally identical elements.

### BRIEF DESCRIPTION OF THE DRAWINGS

It shows, in each case schematically,

FIGS. 1 through 14 each show a top view of a heat exchanger plate with a plate body represented in a transparent manner in different designs,

FIGS. 15 through 17 each show a sectional view in the region of a duct with different duct boundary contours.

### DETAILED DESCRIPTION

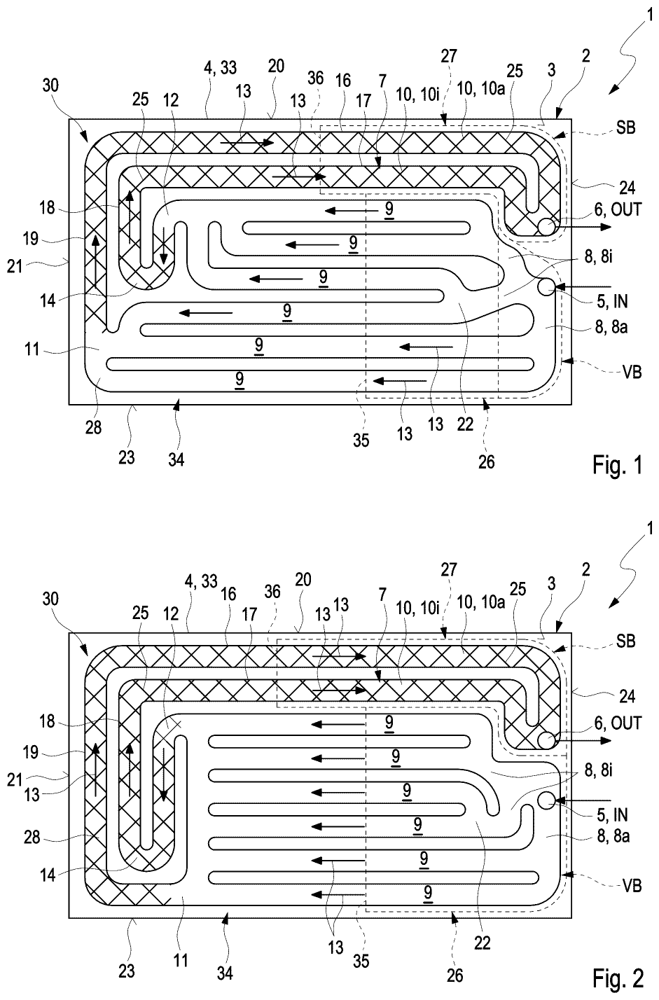

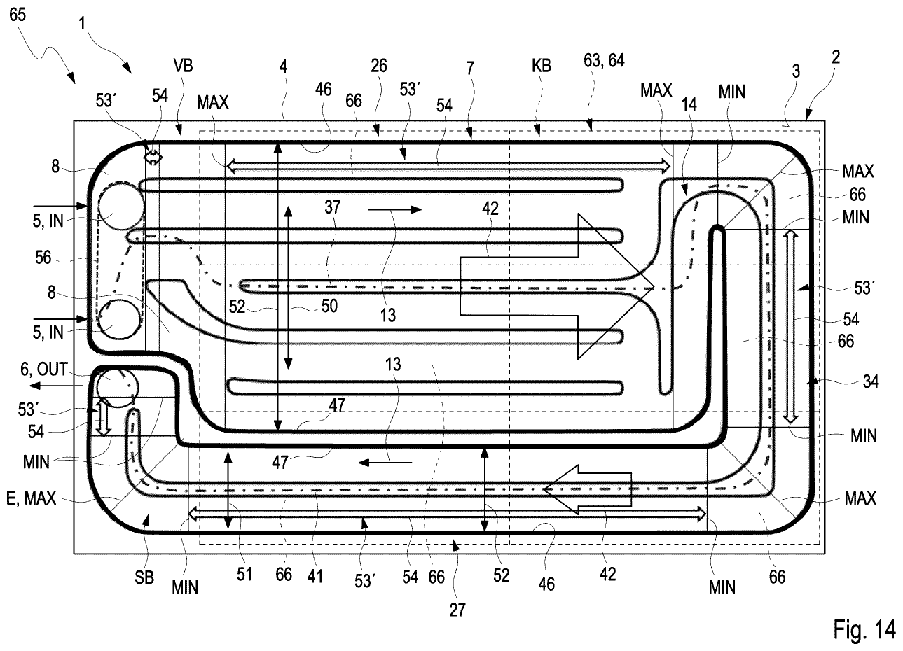

According to FIGS. 1 through 14, a heat exchanger plate 1, which is used to control the temperature of at least one electrical and/or electronic component by means of a liquid temperature control agent, comprises a plate body 2 which has a plate surface 3 for heat-transferring coupling with the respective component to be temperature-controlled. This plate surface 3 can be located on a plate top side facing the observer in the figures. In addition or as an alternative, this plate surface 3 can be located on a plate underside facing away from the viewer in the figures. The component to be temperature controlled is shown only in FIG. 14 with a dashed line and labeled 63. In a preferred application of the heat exchanger plate 1 presented here, the component 63 to be temperature controlled can be a traction battery 64, which is used, for example, in a battery-electric vehicle. FIG. 14 accordingly shows an arrangement of a traction battery 64 on a heat exchanger plate 1. This arrangement 65 will be discussed in more detail below with reference to FIG. 14.

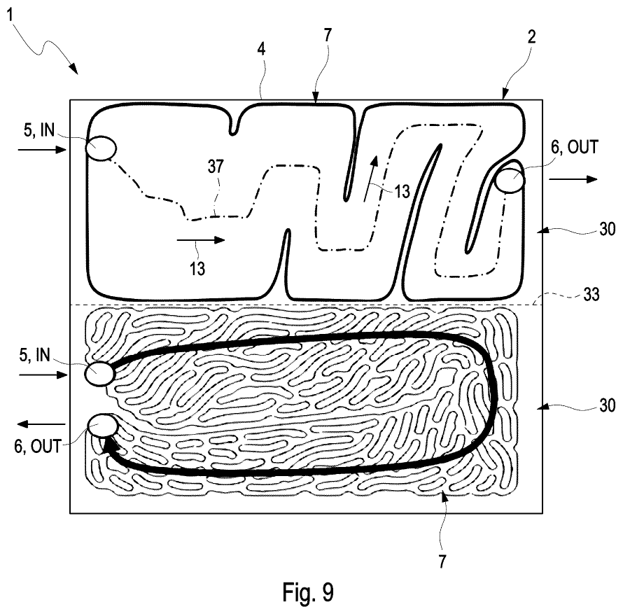

The plate body 2 is configured to be flat and even and has a rectangular geometry, wherein other geometries for the plate body 2 are also conceivable. The plate body 2 has a peripheral plate edge 4 and has at least one temperature control zone 30 within the plate edge 4. In the examples of FIGS. 1 through 7 and 10 through 14, the plate body 2 has only one such temperature control zone 30. In the examples of FIGS. 8 and 9, the plate body 2 has two such temperature control zones 30. It is clear that in other embodiments, the plate body 2 can also have three or more such temperature control zones 30. The features explained below for a temperature control zone 30 can be realized equally for all temperature control zones 30 of the plate body 2. The respective temperature control zone 30 is delimited towards the outside within the plate body 2 by a zone edge 33. In the examples of FIGS. 1 through 7 and 10 through 14, the zone edge 33 coincides with the plate edge 4. In the examples shown in FIGS. 8 and 9, the respective zone edge 33 partially coincides with the plate edge 4. Furthermore, part of the zone edge 33 of one temperature control zone 30 is simultaneously part of the zone edge 33 of the other temperature control zone 30.

The respective temperature control zone 30 has an intake line IN formed on the plate body 2 with at least one intake line connection 5 for supplying the temperature control agent and a discharge line OUT formed on the plate body 2 with at least one discharge line connection 6 for draining the temperature control agent. The supply of the temperature control agent and the drainage of the temperature control agent is indicated by arrows. FIG. 14 shows an example of an embodiment in which the intake line IN has two intake line connections 5. A duct system 7 is formed in the respective temperature control zone 30 in the plate body 2, which serves to guide the temperature control agent and fluidically connects the intake line IN with the discharge line OUT.

The duct system 7 can, according to the examples of FIGS. 1 through 4 and 12 through 14, have at least two distributing ducts 8, which are fluidically connected to the intake line IN 5 and which each branch into a plurality of straight connecting ducts 9. The connecting ducts 9 run parallel to each other for this purpose. The duct system 7 also has at least two collecting ducts 10, which are fluidically connected to the discharge line OUT and into which several of the connecting ducts 9 open.

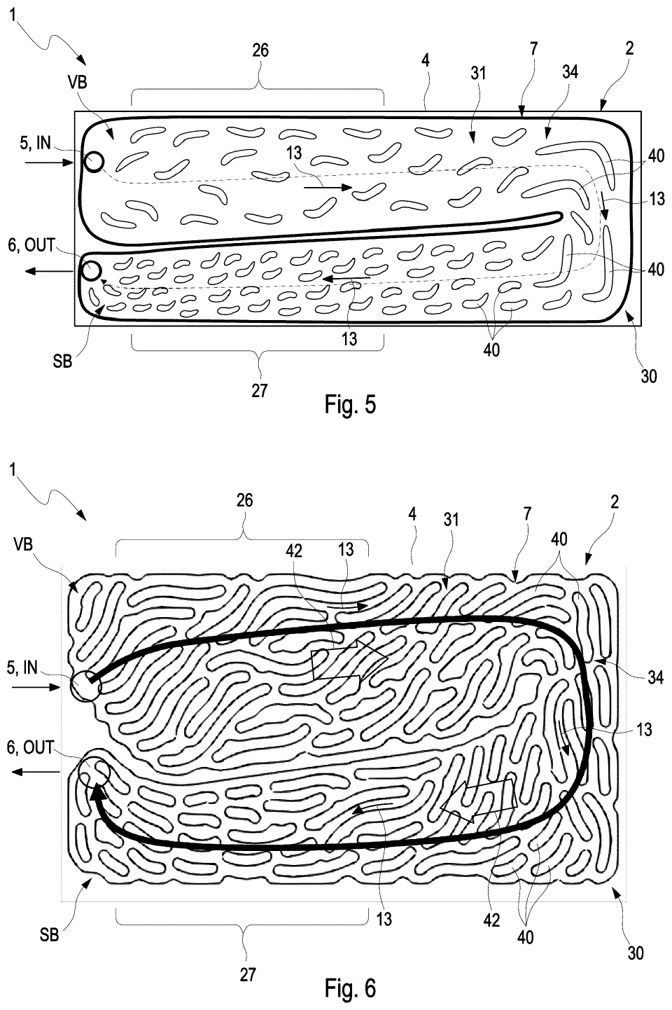

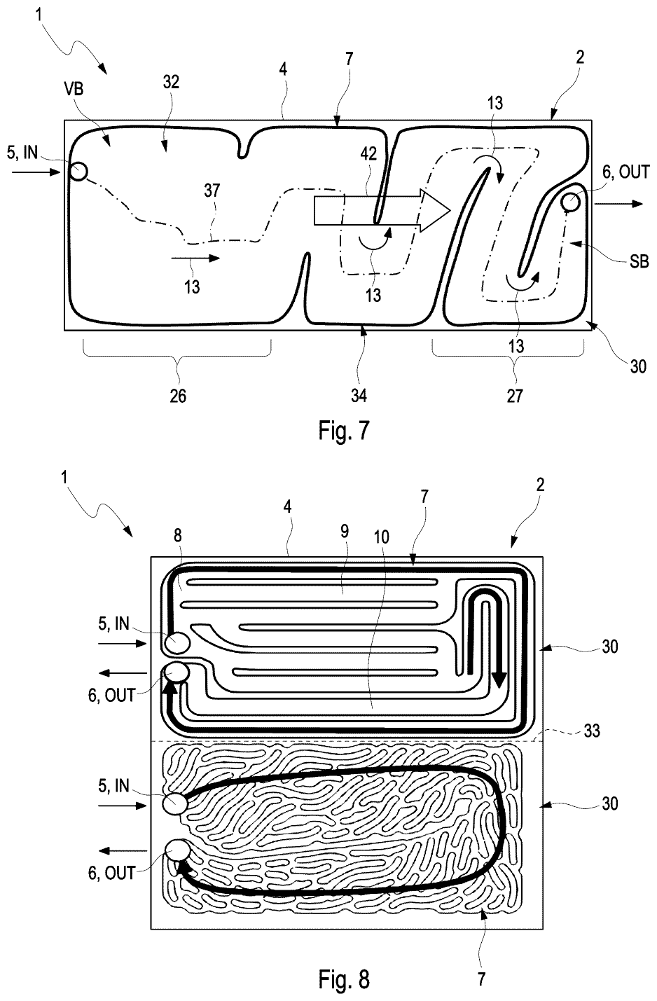

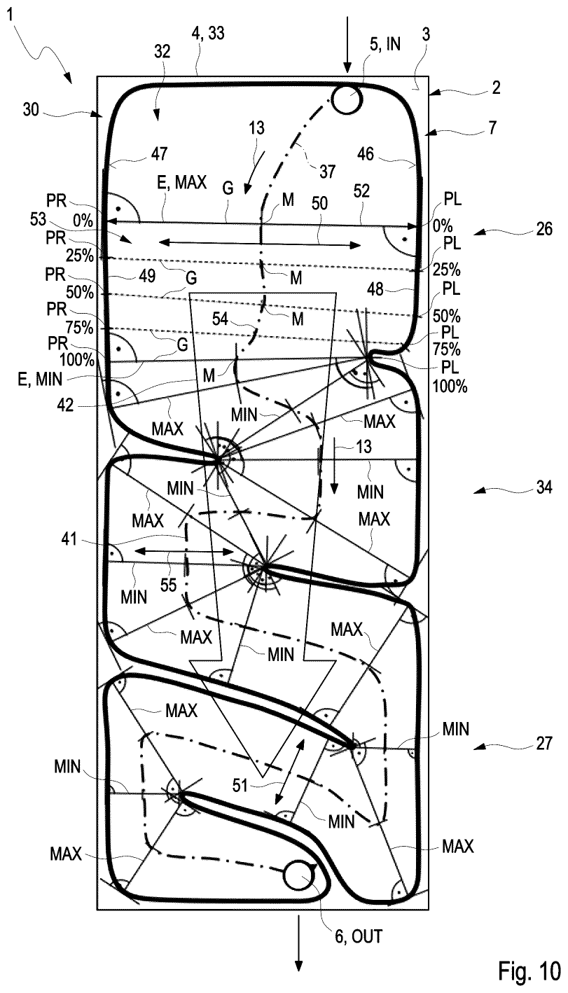

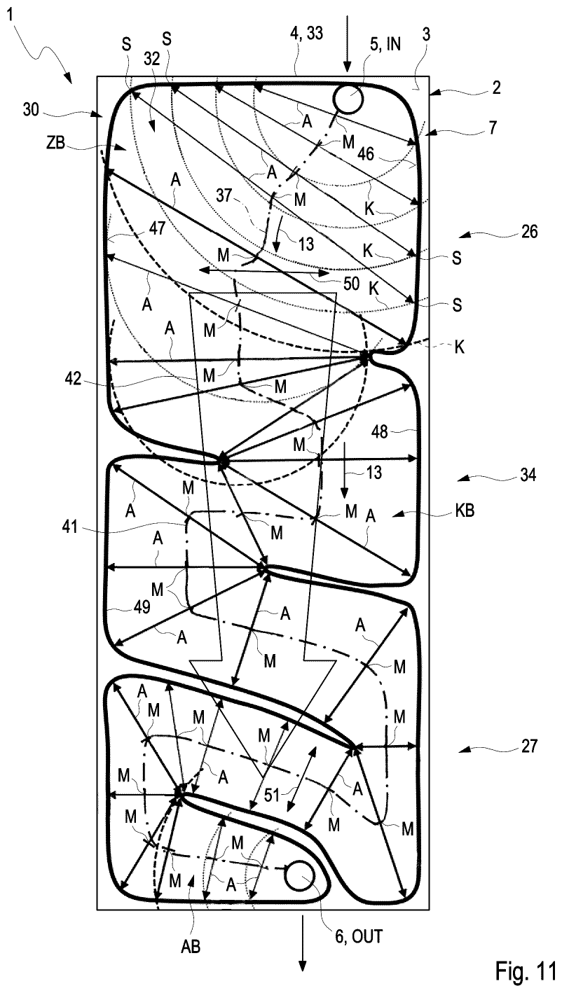

In contrast to this, FIGS. 5, 6, 7, 10 and 11 each show a duct system 7 with only a single duct 31, 32. In the examples of FIGS. 5 and 6, duct 31 has a U-configuration, so that this duct 31 can also be referred to as U-duct 31. In this case, a forward flow region of the U-duct 31 leads away from the intake line IN 5, in FIGS. 5 and 6 from top left to right, while a return flow region of the U-duct 31 leads to the discharge line OUT, in FIGS. 5 and 6 from bottom right to left. In the examples of FIGS. 7, 10 and 11, duct 32 has an I-configuration, so this duct 32 can also be referred to as I-duct 32. In the example of FIGS. 7, 10 and 11, the I-duct 32 leads from the intake line IN to the discharge line OUT with several deflections or baffles, in FIG. 7 from left to right and in FIGS. 10 and 11 from top to bottom.

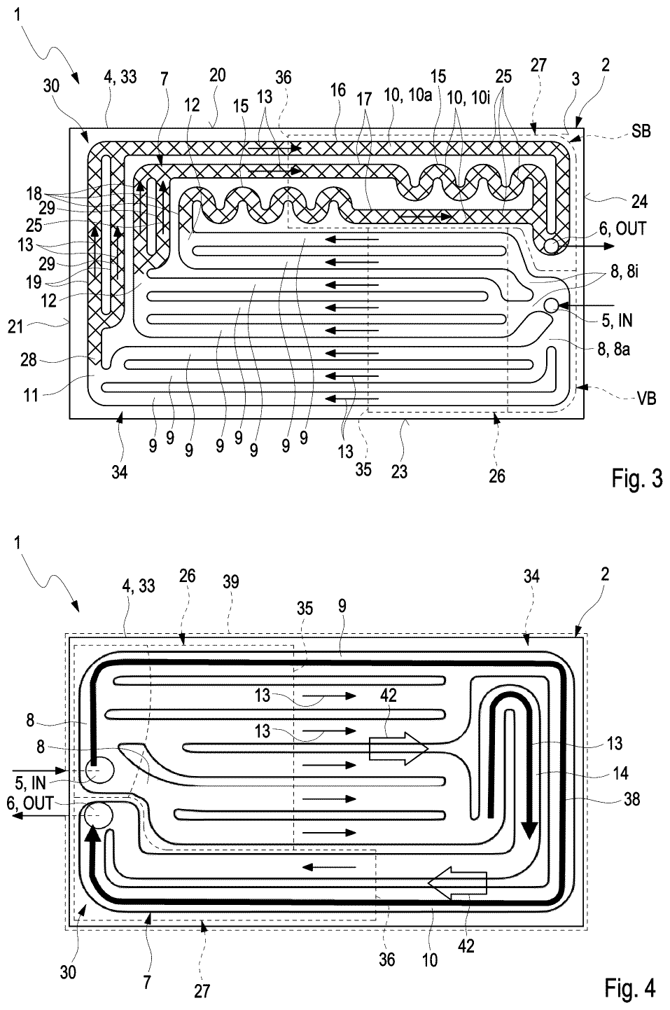

The distributing ducts 8 of FIGS. 1 through 4 and 12 through 14 form at least one inner distributing duct 8i and one outer distributing duct 8a. The outer distributing duct 8a runs closer to the plate edge 4 or zone edge 33 than the respective inner distributing duct 8i. The outer distributing duct 8a is directly adjacent to the plate edge 4, while the inner distributing duct 8i is indirectly adjacent to the plate edge 4. The collecting ducts 10 form an inner collecting duct 10i and an outer collecting duct 10a, wherein the outer collecting duct 10a runs closer to the plate edge 4 than the inner collecting duct 10i. At least two connecting ducts 9, which branch off from the outer distributing duct 8a, open into the outer collecting duct 10a at the start of the outer collecting duct 10a. In the examples of FIGS. 1, 2, 4 and 12 through 14, these are the two outer connecting ducts 9 adjacent to the plate edge 4. In the example of FIG. 3, these are the three outer or outermost connecting ducts 9 arranged adjacent to the plate edge 4. At least two connecting ducts 9, which branch off from the respective inner distributing duct 8i, open into the inner collecting duct 10i at the start of the inner collecting duct 10i. The examples in FIGS. 1, 2, 4 and 12 through 14 are the two connecting ducts 9 adjacent to the collecting ducts 10. In the example shown in FIG. 3, two inner collecting ducts 10i are provided. Three connecting ducts 9, which are adjacent to the three connecting ducts 9 that flow into the outer collecting duct 10a, flow into the inner collecting duct 10i, which is adjacent to the outer collecting duct 10a. The remaining two connecting ducts 9, which are adjacent to this inner collecting duct 10i, open into the other inner collecting duct 10i.

The respective inner collecting duct 10i has an unspecified duct length in a flow direction 13 of the temperature control agent indicated by arrows in the figures, which begins at the start of the duct 12 of the respective inner collecting duct 10i and ends at the outlet connection 6. The outer collecting duct 10a has an unspecified duct length in the flow direction 13 of the temperature control agent, which begins at the start of the duct 11 of the outer collecting duct 10 and ends at the outlet connection 6. The inner collecting duct 10i and the outer collecting duct 10a run in the plate body 2 in such a way that the duct length of the inner collecting duct 10i is at least 75% of the duct length of the outer collecting duct 10a. The aim is for the inner collecting duct 10i to have almost the same duct length as the outer collecting duct 10a. The duct length of the respective inner collecting duct 10i can therefore also be at least 80% or at least 85% or at least 90% or at least 95% or approximately 100% of the duct length of the outer collecting duct 10a.

In the examples of FIGS. 1, 2, 4, 13 and 14, the inner collecting duct 10i may have a loop section 14 that increases the duct length of the inner collecting duct 10i. In the example of FIG. 3, the respective inner collecting duct 10i has a meandering section 15.

The respective inner collecting duct 10i and the outer collecting duct 10a each have two longitudinal sections 16, 17, 18, 19, in which the inner collecting duct 10i and the outer collecting duct 10a run parallel to adjacent longitudinal sections 20, 21 of the plate edge 4. In FIGS. 1 through 4, the outer collecting duct 10a has a longitudinal section 16 at the top that runs parallel to the upper longitudinal section 20 of the plate edge 4. The outer collecting duct 10a also has a longitudinal section 19, which can be seen on the left in FIGS. 1 through 4, 13 and 14, and which runs parallel to the adjacent left longitudinal section 21 of the plate edge 4. The respective inner collecting duct 10i has, in FIGS. 1 through 4, 13 and 14, a longitudinal section 17 that runs parallel to the upper longitudinal section 20 of the plate edge 4, and on the left a longitudinal section 18 that runs parallel to the left longitudinal section 21 of the plate edge 4.

In the examples of FIGS. 1, 2, 4, 13 and 14, a connecting duct 9 branching off from one of the inner distributing ducts 8i opens into the outer collecting duct 10a. In FIGS. 1, 2, 4, 13 and 14, this is the third connecting duct from the bottom. This branches off at the end of one duct 22 of the one inner distributing duct 8i and opens into the outer collecting duct 10a at the start of the duct 11 of this outer collecting duct 10a. The other connecting duct 9, which branches off at the end of duct 22 of this distributing duct 8i, opens into the inner collecting duct 10i at the start of duct 12.

Since the plate body 2 here is configured rectangular, the plate edge 4 has two longer longitudinal sections 20 and 23, which run horizontally in FIGS. 1 through 7, 13 and 14, and two shorter longitudinal sections 21 and 24, which run vertically in FIGS. 1 through 7, 13 and 14. The longer longitudinal sections 20 and 23 run parallel to each other and perpendicular to the two shorter longitudinal sections 21, 24, which in turn run parallel to each other. The longer longitudinal sections 20, 23 extend parallel to the connecting ducts 9. Accordingly, the longitudinal sections 16 and 17 of the collecting ducts 10 run parallel to the connecting ducts 9. The same also applies to the embodiments of FIGS. 8 and 9, in which the plate body 2 has two temperature control zones 30, wherein the longitudinal sections then refer to the rectangular temperature control zone 30 or to its zone edge 33.

According to a favorable embodiment, the duct system 7 is configured such that the distributing ducts 8 have a smaller heat transfer coefficient than the collecting ducts 10 and/or than the connecting ducts 9. In particular, it may be the case that the collecting ducts 10 have a larger heat transfer coefficient than the connecting ducts 9. This can be achieved by various measures. The following measures can be implemented individually or cumulatively or in any combination. For example, the cross-section of the respective collecting duct 10 through which flow is possible can be smaller than the sum of the cross-sections of the connecting ducts 9 through which flow is possible and which open into it. Since in FIGS. 1 through 3 a width of the respective duct, measured in the plane of the plate body 2 and transverse to the air flow direction 13, is essentially constant, the cross-section of the respective duct through which air can flow can be determined in particular by a duct height measured perpendicular to the plane of the plate body 2. In addition, the cross-section through which flow can take place is reduced by heat-conducting elements that may be arranged in the ducts. In the examples of FIGS. 1 and 2, three connecting ducts 9 each flow into the respective collecting duct 10. In the example of the FIG. 3, two connecting ducts 9 flow into one inner collecting duct 10i, while three connecting ducts 9 flow into the other inner collecting duct 10i and into the outer collecting duct 10a. This makes it relatively easy to make the cross-section of the respective collecting duct 10 smaller than the sum of the cross-sections of the connecting ducts 9 that open into it. In addition or as an alternative, it may be provided that a flow resistance in the respective collecting duct 10 is greater than in the connecting ducts 9 that open into it. In addition or as an alternative, heat-conducting elements 25 can be arranged or formed in the collecting ducts 10, which are indicated in the figures by hatching. The heat-conducting elements 25 are configured to enhance the transfer of heat between the temperature control agent and the plate body 2. The heat-conducting elements 25 can be made of a heat-conducting material, preferably a metal, and have a surface that is exposed to the temperature control agent and are conveniently in direct contact with the plate body 2. The heat-conducting elements 25 can be configured as turbulators, fins or lamellae, or a combination of these. The heat-conducting elements 25 may be separate components inserted in the collecting ducts 10 or integrally formed on the plate body. In contrast to this, it may be envisaged that the connecting ducts 9 do not contain any such heat-conducting elements 25. However, if heat-conducting elements 25 are arranged in the collecting ducts 10 and in the connecting ducts 9, it is expedient to provide that the heat-conducting elements 25 arranged in the collecting ducts 10 have a larger number and/or a larger arrangement density and/or a larger surface exposed to the temperature control agent and/or a larger heat conductivity than the heat-conducting elements arranged in the connecting ducts 9.

The duct system 7 has a total duct system length 41 from the intake line IN to the discharge line OUT, which is only shown in FIGS. 10, 11, 13 and 14. The duct system 7 has an entry region 26, which is indicated by a broken line in FIGS. 1 through 3 and by a curly bracket in FIGS. 5 through 7, and which extends over 20% to 40%, preferably over 25% to 35% of the total duct system length 41. The duct system 7 also has an exit region 27, which is indicated by a broken line in FIGS. 1 through 3 and by a curly bracket in FIGS. 5 through 7 and which extends over 20% to 40%, preferably over 25% to 35% of the total duct system length 41. A connecting region 34 of the duct system 7 connects the entry region 26 with the exit region 27.

A number of ducts in the exit region 27 is in the range from 20% to 70% of a number of ducts in the entry region 26. In the examples of FIGS. 1, 2, 4, 13 and 14, there are two ducts in the exit region 26, namely the two collecting ducts 10, while there are six connecting ducts 9 in the entry region 27. In the example of FIG. 3, three collecting ducts 10 are arranged in the exit region 27, while eight connecting ducts 9 are located in the entry region 26. In particular, the number of connecting ducts 9 is at least twice as large or more than twice as large as a number of collecting ducts 10. In FIGS. 1, 2, 4, 13 and 14, six connecting ducts 9 meet two collecting ducts 10. In the example shown in FIG. 3, eight connecting ducts 9 meet three collecting ducts 10.

In the preferred embodiments shown in FIGS. 1 through 6 and 12 through 14, the intake line IN and discharge line OUT are arranged next to each other on the plate body 2, in the region of one longitudinal end of the plate body 2 and in the vicinity of the plate edge 4, respectively. This results in a U-configuration. The outer distributing duct 8a, the adjacent connecting duct 9 to the plate edge 4 or to the zone edge 33, i.e. the lowest connecting duct 9 in FIGS. 1 through 3, and the outer collecting duct 10a form an edge duct 28 in the duct system 7, which runs around the plate edge 4 and fluidically connects the intake line IN to the discharge line OUT.

In the examples of FIGS. 2, 4, 13 and 14, the loop in loop section 14 is more pronounced or longer than in the example of FIG. 1. In the examples of FIGS. 2, 4, 13 and 14, this is also accompanied by a shortening of the connecting ducts 9, which branch off from the outer distributing duct 8a.

In the example shown in FIG. 3, two inner collecting ducts 10i are provided. Three connecting ducts 9 lead into one inner collecting duct 10i. Two connecting ducts 9 flow into the other inner collecting duct 10i. Three connecting ducts 9 flow into the outer collecting duct 10a. The outer collecting duct 10a and the adjacent inner collecting duct 10i each have two longitudinal sections 18 and 19, respectively, that run parallel to the longitudinal section 21 of the plate edge 4, in a region that faces the longitudinal section 21 of the plate edge 4, which is on the left in FIG. 3. For this purpose, each collecting duct 10 has a parallel duct 29 in this region, which branches off and rejoins the collecting duct 10.

In the case of the heat exchanger plate 1 presented here, the respective duct system 7 is configured in such a way that a cross-section of the duct system 7 through which flow can take place is larger in the entry region 26 leading away from the intake line IN than in the exit region 27 leading to the discharge line OUT. To homogenize the heat transfer performance along the duct system 7, the reduced temperature difference in the exit region 27 can be largely compensated by the higher flow velocity in the exit region 27.

Preferably, the duct system 7 has the total duct system length 41 from the intake line IN to the discharge line OUT, wherein the duct system 7 has the entry region 26, which extends over about ⅓ of the total duct system length 41, the exit region 27, which extends over about ⅓ of the total duct system length 41, and the connecting region 34, which connects the entry region 26 to the exit region 27 and can also be about ⅓ of the total duct system length 41. Furthermore, it may be provided that a cross-section of the entry region 26 that can be flowed through is at least 50% larger at its transition 35 to the connecting region 34 than a cross-section of the exit region 27 that can be flowed through at its transition 36 to the connecting region 34.

It is advisable for the cross-section through which the flow passes to increase starting from the intake line IN and then essentially only decrease along the entry region 26, the connecting region 34 and the exit region 27 up to the discharge line OUT 27.

It may be advantageous to provide that the cross-section of the entry region 26 through which flow is possible lies at its transition 35 to the connecting region 34 in a range of 70% to 600%, preferably in a range of 100% to 400%, of the cross-section of the exit region 27 through which flow is possible at its transition 36 to the connecting region 34, in each case including the region boundaries.

According to one embodiment, it can also be provided that a mean cross-section, through which flow can take place, of the ducts 8, 9, 31, 32 running in the entry region 26 is at least 50% larger than a mean cross-section, through which flow can take place, of the ducts 9, 10, 31, 32 running in the exit region 27. In particular, it may be provided that the mean cross-section of the ducts 8, 9, 31, 32 extending in the entry region 26 is in a range from 70% to 600%, preferably in a range from 100% to 400%, of the mean cross-section through which flow can take place of the ducts 9, 10, 31, 32 extending in the exit region 27.

Optionally, it may be stipulated that the mean cross-section of ducts 8, 9, 31, 32 of the entry region 26 is averaged over the length of the entry region 26 and/or that the mean cross-section of ducts 9, 10, 31, 32 of the exit region 27 is averaged over the length of the exit region 27. In particular, it may be stipulated that the mean cross-section of the ducts 8, 9, 31, 32 of the entry region 26 is averaged over the effective length of the entry region 26 and/or that the mean cross-section of ducts 9, 10, 31, 32 of the exit region 27 over which flow can take place is averaged over the effective length of the exit region 27.

The effective length of a straight duct section can be defined as the distance from the inlet to the outlet of the straight duct section. In the case of a duct section corrugated transversely to a main flow direction 42, the effective length can be formed by the distance measured in the main flow direction 42 from the inlet to the outlet of the duct section corrugated transversely to the main flow direction 42. The effective length can be formed by the sum of the lengths of the two straight duct sections in a loop-shaped duct section, which has two straight duct sections, a duct section bent through 180°, which connects the two straight duct sections with each other, and two duct sections bent through 90°, which connect the respective straight duct section with an inlet or with an outlet of the loop-shaped duct section. In the case of a loop-shaped duct section that has three straight duct sections and two duct sections bent through 180°, each of which connects two of the straight duct sections to one another, the effective length can be formed by the distance from the inlet of the first straight duct section, which is connected to the second straight duct section via the first bent duct section, to the outlet of the third straight duct section, which is connected to the second straight duct section via the second bent duct section.

The cross-section of the respective duct through which air can flow is essentially determined by the duct height measured perpendicular to the plate plane and the duct width measured perpendicular to the duct height. The cross-section to be considered extends perpendicular to a neutral fiber or centerline 37 of the respective duct as shown in FIGS. 7, 10, 11, 13 and 14. For a duct with essentially straight lateral duct boundaries, the centerline 37 corresponds to half the distance between the lateral duct boundaries. However, if the sides of the duct are not straight, determining the neutral centerline 37 and thus the cross-section to be considered is comparatively complex. In principle, flow simulations can be used to determine the centerline 37 and thus the cross-sections through which the flow must pass.

The cross-section through which the medium flows describes the clear opening width available to the temperature control agent, i.e. the opening cross-section resulting from the width and height, minus knobs, beads and other contouring. For each point of the duct system 7, the duct width is determined as a section through the duct system 7. The cross-section of the duct that can be flowed through is the cross-section of the opening available to the temperature control agent in this section. The preferred length of the duct system's duct length or in the entry region, in the connecting region and in the exit region is the length of the centerline 37 in the respective duct region. The options for determining the total duct system length 41 will be discussed in more detail below with reference to FIGS. 10, 11, 13 and 14.

The duct system 7 can have an external path 38, which is only designated in FIG. 4 here as a representative example of all the embodiments shown in FIGS. 1 through 14. This outer path 38 is formed by one of the distributing ducts 8, one of the connecting ducts 9 and one of the collecting ducts 10 and extends along one zone edge 33 of the temperature control zone 30. The outer path 38 is a maximum of 30% longer than the shortest connecting path 39, which is indicated by a broken line in FIG. 4. The shortest connection path 39 leads directly from the intake line IN to the zone edge 33, along the zone edge 33 and the outer path 38, and from the zone edge 33 directly to the discharge line OUT, along the shortest path. Typically, such an outer path 38 can form the longest path within the respective temperature control zone 30. The measure presented here ensures that this longest path is as short as possible, namely a maximum of 30% longer than the shortest possible path along the zone edge 33 to connect the intake line IN with the discharge line OUT 39.

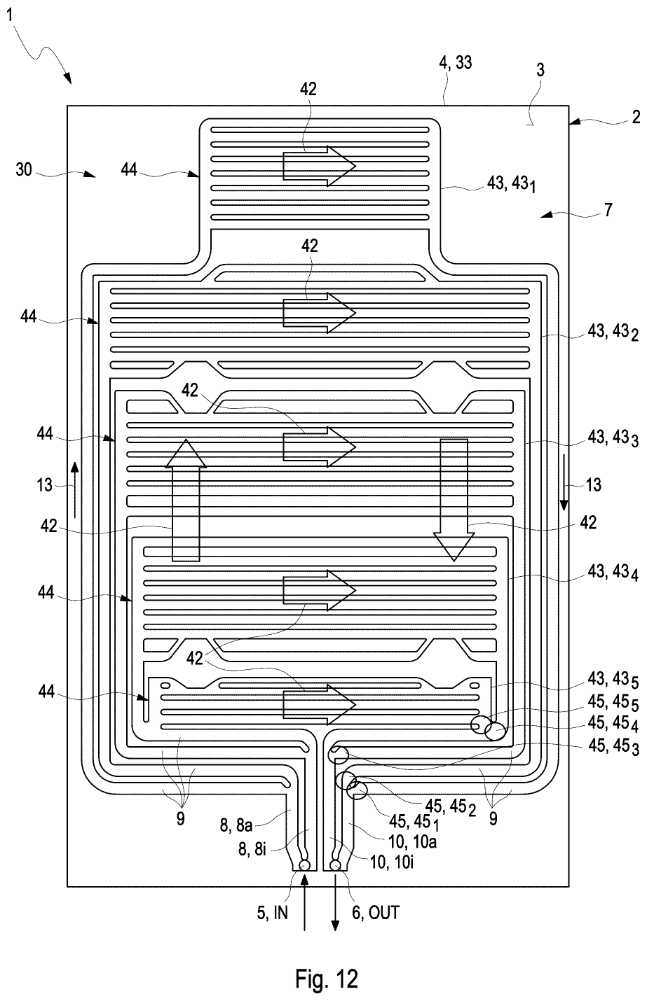

The duct system 7 can have several paths 43, as shown in FIG. 12, each of which guides the temperature control agent from the intake line IN through one of the distributing ducts 8, one of the connecting ducts 9 and one of the collecting ducts 10 to the discharge line OUT and each of which has a path length. These paths 43 can have different path lengths. In the example of FIG. 12, five paths 43 are provided, each having a parallel zone 44 with several parallel ducts 45 that are not further specified and through which flow occurs in parallel. The five paths 43 form a first path 43₁, a second path 43₂ that is shorter than the first path 43₁, a third path 43₃ that is shorter than the second path 43₂, a fourth path 43₄, which is shorter than the third path 43₃, and a fifth path 43₅, which is shorter than the fourth path 43₄. In the parallel zone 44 of the first path 43₁, the path length varies from 93% to 100% in the example shown. In the parallel zone 44 of the second path 43₂, the path length varies from 63% to 67% in the example shown. In the parallel zone 44 of the third path 43₃, the path length varies from 51% to 59% in the example shown. In the parallel zone 44 of the fourth path 43₄, the path length varies from 38% to 46% in the example shown. In the parallel zone 44 of the fifth path 43₅, the path length in the example shown is about 33%. The percentages refer to the longest path 43, which is defined in the first path 43₁ by the outermost duct in the parallel zone 44 and thus determines the 100%.

The path 43, which has the largest path length, defines the longest path. In the example of FIG. 12, the first path 43₁ has the largest path length. In a favorable embodiment, it is provided that each path 43 whose path length is less than 50% (case A), in particular less than 60% (case B), preferably less than 75% (case C), of the path length of the longest path 43₁, forms a short path. In case A, the fifth path 43₅ and the fourth path 43₄ each form a short path 43. In case B, the fifth path 43₅, the fourth path 43₄ and the third path 43₃ each form a short path 43. In case C, the fifth path 43₅, the fourth path 43₄, the third path 43₃ and the second path 43₂ each form a short path 43.

In FIG. 12, a position is marked with a circle for each path 43, which has the smallest cross-section 45 that can be flowed through within the respective path 43. Marked here exemplarily on the downstream side of the respective parallel zone 44 the smallest cross-section 45₁ through which flow is possible for the first path 43₁, the smallest cross-section 45₂ through which flow is possible for the second path 43₂, the smallest small cross-section 45₃ of the third path 43₃, the smallest cross-section 45₄ of the fourth path 43₄ and the smallest cross-section 45₅ of the fifth path 43₅.

A configuration of duct system 7 is preferred in which the sum of the smallest cross-sections 45 through which air can flow of all short paths 43 is less than 40%, in particular less than 20%, preferably less than 10%, of the sum of the smallest cross-sections 45 through which air can flow of all other paths 43. In this case, “all other paths 43” includes at least the longest path 43₁ and—if available—every other path 43 that is not considered a short path 43.

In case A, where the path length of the short paths 43 is less than 50% of the path length of the longest path 43₁, “all other paths 43” include the longest path 43₁ and every other path 43 whose path length is greater than 50% of the path length of the longest path 43₁, i.e. the third path 43₃ and the second path 43₂. In case B, where the path length of the short paths 43 is less than 60% of the path length of the longest path 43₁, the other paths 43 include every path 43 whose path length is greater than 60% of the path length of the longest path 43₁, i.e. the second path 43₂. In case C, where the path length of the short paths 43 is smaller than 75% of the path length of the longest path 43₁, the other paths include every path whose path length is greater than 75% of the path length of the longest path 43₁, but no further path 43 in addition to the longest or first path 43₁.

These further or other paths 43 can also be seen as long paths 43. If two or more paths 43 with the same path length exist that are longer or greater than the path length of all other paths 43, one of these paths 43 can form the longest path 43, while the other path or paths 43 then form a long path 43 or one of the other paths 43 respectively.

While FIGS. 1 through 6 and 12 through 14 show examples of duct systems 7 with a U-configuration, FIGS. 7, 10 and 11 show variants in which the duct system 7 has an I-configuration. The intake line IN and the discharge line OUT are arranged on the plate body 2 at opposite end sections of the plate body 2. In FIGS. 1 through 4 and 12 through 14, the duct system 7 has several ducts, namely several distributing ducts 8, several connecting ducts 9 and several collecting ducts 10. In contrast to this, the duct system 7 in FIGS. 5 through 7, 10 and 11 has only a single duct 31, 32. These ducts 31, 32 can be configured in a meandering manner, i.e. they can have a meandering course to connect the intake line IN with the discharge line OUT.

In the embodiments of FIGS. 5 and 6, the U-duct 31 has a plurality of separate, dissimilar and asymmetrically distributed flow-directing and heat transfer contours 40 around which the temperature control agent can flow. In the example of FIG. 5, the number and density of contours is 40 smaller than in the example of FIG. 6. In both embodiments, the contours 40 formed in the exit region 27 differ from the contours 40 arranged in the entry region 26 in terms of their greater density of arrangement and/or smaller distances between them and/or smaller dimensions.

FIGS. 1 through 7 and 10 through 14 each show configurations of heat exchanger plate 1 in which the plate body 2 has only a single temperature control zone 30. In contrast to this, FIGS. 8 and 9 show two examples of embodiments in which the plate body 2 has two such temperature control zones 30 within the plate edge 4. The two temperature control zones 30 are arranged one above the other in the illustrations in FIGS. 8 and 9. The two temperature control zones 30 each have an intake line IN, formed on the plate body 2, for supplying the temperature control agent, a discharge line OUT, formed on the plate body 2, for draining the temperature control agent, and a duct system 7, formed in the plate body 2, for guiding the temperature control agent, which fluidically connects the intake line IN to the discharge line OUT. Thus, the plate body 2 has two separate intake lines IN, two separate discharge lines OUT and two separate duct systems 7. It may be useful to provide that the two temperature control zones 30 are designed differently with regard to the respective intake line IN, the respective discharge line OUT and the respective duct system 7. In FIG. 8, the upper temperature control zone 30 is designed like the temperature control zone 30 shown in FIGS. 4, 13 and 14, while the lower temperature control zone 30 is designed like the temperature control zone 30 shown in FIG. 6. In FIG. 9, on the other hand, the upper temperature control zone 30 is designed like the temperature control zone 30 shown in FIGS. 7, 10 and 11, while the lower temperature control zone 30 is again designed like the temperature control zone 30 shown in FIG. 6.

According to FIGS. 1 through 14, the duct system 7 defines a main flow direction 42 for the temperature control agent flowing in the duct system 7 from the intake line IN to the discharge line OUT, which is indicated by one or more arrows. The duct system 7 assigns a left duct boundary contour 46 and a right duct boundary contour 47 to the main flow direction 42, which, as representative of all embodiments, are provided with reference characters only in FIGS. 10 and 11 as well as 13 and 14. In FIGS. 10 and 11, the main flow direction 42 is oriented from top to bottom, so that the left duct boundary contour 46 in FIGS. 10 and 11 is on the right side, while the right duct boundary contour 47 in FIGS. 10 and 11 is on the left side. The two duct boundary contours 46, 47 delimit a cross-section of the duct system 7 available for the temperature control agent to flow through, perpendicular to the main flow direction 42. If, for explanatory purposes, the duct system 7 is considered to be a riverbed, then the left duct boundary contour 46 and the right duct boundary contour 47 form a left bank and a right bank of the riverbed.

The duct system 7 defines a left minimum distance 48, which leads from the intake line IN along the left duct boundary contour 46 to the discharge line OUT, and a right minimum distance 49, which leads from the intake line IN along the right duct boundary contour 47 to the discharge line OUT. In doing so, the shortest, direct path is taken into account for the determination of the respective minimum distance 48, 49 for the connection from the intake line IN or discharge line OUT to the respective duct boundary contour 46, 47.

For an intake line IN with only one intake line connection 5, the geometric center of the intake line connection 5 is used as the starting point of the centerline 37. For an intake line IN that has multiple intake line connections 5 as shown in FIG. 14, the geometric center of an envelope 56 that envelops the intake line connections 5, referred to as the “envelope”, is used as the starting point of the centerline 37. The same applies to the discharge line OUT if it only has one discharge line connection 6 or several discharge line connections 6.

From the intake line IN to the discharge line OUT, the duct system 7 has the total duct system length 41 already mentioned above. The duct system is further configured such that the total duct system length is at most 50% or at most 40% or at most 30% or at most 25% or at most 20% or at most 15% or at most 10% or at most 5% or maximum 0% greater than the greater of left minimum distance 48 and right minimum distance 49, when the two minimum distances 48, 39 are different, or maximum 50% or maximum 40% or maximum 30% or maximum 25% or maximum 20% or maximum 15% or maximum 10% or maximum 5% or maximum 0% greater than the left minimum distance 48 or than the right minimum distance 49, if the left minimum distance 48 and the right minimum distance 49 are the same size. In the examples of FIGS. 10 and 11, the right minimum distance is greater than the left minimum distance. Likewise, according to particularly advantageous embodiments, the configuration of the duct system 7 can be chosen so that the total duct system length 41 is at most equal to or even smaller than the larger of the left minimum distance 48 and the right minimum distance 49, if the two minimum distances 48, 39 are of different sizes, or at most equal to or smaller than the left minimum distance 48 or the right minimum distance 49, if the left minimum distance 48 and the right minimum distance 49 are of the same size.

A mean entry region cross-section 50 available to the temperature control agent in the entry region 26 for flow through is larger than a mean exit region cross-section 51 available to the temperature control agent in the exit region 27 for flow through. The respective mean cross-section 50, 51 is indicated by a double arrow in FIGS. 10, 11, 13 and 14. In duct system 7, in the main flow direction 42, a distance 52 between the left duct boundary contour 46 and the right duct boundary contour 47 varies only in FIGS. 10, 13 and 14. Furthermore, the duct system 7 between the intake line IN and the discharge line OUT has at least one duct section 53 which extends in the main flow direction 42 from one extremum E of the distance 52 to the next following extremum E of the distance 52. The respective extremum E defines a maximum MAX or a minimum MIN and is defined by the fact that in the respective extremum E, a straight line G running along the distance 52 is perpendicular to the left duct boundary contour 46 and perpendicular to the right duct boundary contour 47. FIG. 10 shows a representative duct section 53 in the entry region 26, which leads in the main flow direction 42 from a maximum MAX at the beginning of the duct section 53 to a minimum MIN at the end of the duct section 53.

Each duct section 53 has a section length 54 measured along the centerline 37 of the duct section 53. The section length 54 thus represents the distance from the beginning or maximum MAX along the centerline 37 to the end or minimum MIN of the respective duct section 53. The centerline 37 is formed by the center points M of straight lines G or connecting straight lines G, which in each case connect a point PL of the left duct boundary contour 46, which has a percentage length portion between the two extrema E lying in the range from 0% to 100% at the left duct boundary contour 46, with a point PR of the right duct boundary contour 47, which has the same percentage length portion between the extrema E at the right duct boundary contour 47. As an example, FIG. 10 shows six straight lines G that connect six left points PL, which lie at 0%, 25%, 50%, 75% and 100% of the length of the left duct boundary contour 46, with six right points PR, which lie at 0%, 25%, 50%, 75% and 100% of the length of the right duct boundary contour 47. The straight line G that connects the points PL, PR at 0% corresponds to the maximum MAX at the beginning of the duct section 53 and the straight line G that connects the points PL, PR at 100% corresponds to the minimum MIN at the end of the duct section 53.

The total duct system length 41 is formed by the sum of the section lengths 54 of all consecutive duct sections 53 from the intake line IN to the discharge line OUT. In the example of FIG. 10, the canal system 7 between the intake line IN and the discharge line OUT shows nineteen extrema E. The intake line IN and the discharge line OUT each also form an extremum E, namely a minimum MIN in each case. In the example shown in FIG. 10, the duct system 7 has twenty duct sections 53, each of which is bounded in the main flow direction 42 by a minimum MIN and a maximum MAX or by two extrema E. duct sections 53 that immediately follow one another in the main flow direction 42 adjoin one another via a common extremum E. Thus, the entry region 26, the exit region 27 and also the connecting region 34 each have several duct sections 53.

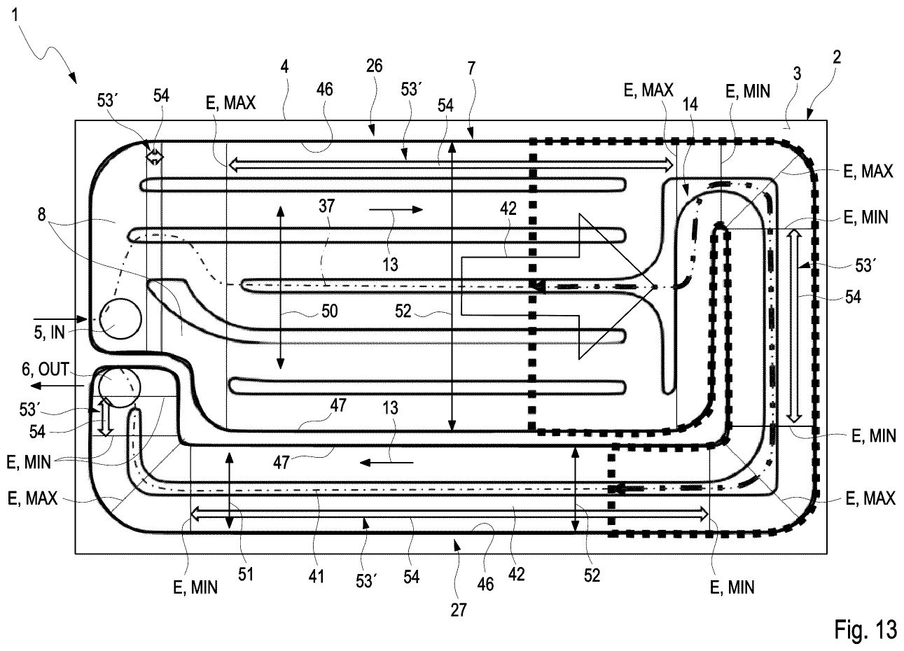

The duct systems 7 are designed identically in the examples in FIGS. 4, 13 and 14. In addition to duct sections 53, in which the distance 52 increases from a minimum MIN to a maximum MAX or decreases from a maximum MAX to a minimum MIN, there are also several duct sections 53′ in each of which the distance 52 between the left and right duct boundary contours 46, 47 is constant. The duct sections 53′ with a constant distance 52 are marked in FIGS. 13 and 14 by double arrows, each of which represents the section length 54 of the respective duct section 53′. In such duct sections 53′ in which the distance 52 is constant, this duct section 53′ extends along the extremum E, which can be a minimum MIN or a maximum MAX, so that at the beginning and at the end of such a duct section 53′ there can be a maximum MAX or a minimum MIN, forming the transition to the adjacent duct section 53. In such a duct section, the distance forms an unspecified plateau.

The mean entry region cross-section 50 is now formed by an entry region volume available for the temperature control agent to flow through in the entry region 26, based on the entry region length. In the same way, the mean exit region cross-section 51 is formed by an exit region volume available for the temperature control agent to flow through in the exit region 27, based on the exit region length. The entry region length can preferably be formed by the sum of the section lengths 54 of all duct sections 53 located in the entry region 26. The exit region length can then be formed by adding the lengths of all the duct sections 54 in the exit region 27. It is advisable to configure the duct system 7 so that the mean entry region cross-section 50 is at least 50% larger than the mean exit region cross-section 51. A configuration is particularly useful in which the mean entry region cross-section 50 is in a range from 70% to 600%, preferably from 100% to 400%, of the mean exit region cross-section 51.

A mean cross-section of the connecting region 55 available for the temperature control agent to flow through in the connecting region 34 is indicated in FIG. 10 by a double arrow and is appropriately smaller than the mean entry region cross-section 50 and larger than the mean exit region cross-section 51. The mean cross-section of the connecting region 55 is formed by a connecting region volume available for the temperature control agent to flow through in the connecting region 34, relative to a connecting region length which extends from the entry region 26 to the exit region 27. Here, too, it can be provided that the length of the connecting region is formed by the sum of the lengths of the sections 54 of all the duct sections 53 located in the connecting region 34.

It may be useful to provide that the duct system 7 has a smaller heat transfer coefficient in the entry region 26 than in the exit region 27 and/or than in the connecting region 34.

In the following, an alternative approach for determining the centerline 37 and thus the respective duct length is presented on the basis of FIG. 11.

The cross-section through which the medium flows describes the clear opening width available to the temperature control agent, i.e. the opening cross-section resulting from the width and height, minus knobs, beads and other contouring. For each point of the duct system 7, the duct width is determined as a section through the duct system 7 according to FIG. 11. The cross-section of the duct 32 that can be flowed through is the cross-section of the opening available to the temperature control agent in this section. The duct length of the duct system 7 or in the entry region 26, in the connecting region 34 and in the exit region 27 is preferably the length of the centerline 37 in the respective duct region.

The centerline 37 for the entry region 26, the connecting region 34 and the exit region 27 can be determined as follows, for example. The centerline 37 represents here the center points M of distances A between the lateral duct boundary contours 46, 47, which are indicated by double arrows in FIG. 11 and which follow one another in the main flow direction 42 of the temperature control agent. These distances A represent a duct diameter perpendicular to the centerline 37 and can be determined as follows, for example, for an intake line region ZB, a duct region KB and a discharge line region AB.

In the intake line region ZB, in which the intake line IN is located, circles K are generated centrically to the intake line IN, which each have an intersection S with both duct boundary contours 46, 47. The two points of intersection S of the respective circle K are connected to one another by a straight line that defines the respective distance A of the duct boundary contours 46, 47 or the duct diameter. The geometric center of this distance A or diameter is the midpoint M, which represents a point on the centerline 37. With increasing distance A between the duct boundary contours 46, 47, the connection of the points of intersection S with the duct boundary contours 46, 47 results in sections through the duct with increasing distance A or duct diameter and thus an increasing cross-section that can be flowed through. An end to the intake line region ZB is reached when at least one of the following criteria is met:
a) As soon as the diameter of the circle K becomes so large that three contact points and/or intersection points S arise between the circles K and the two duct boundary contours 46, 47.
b) As soon as the circle K runs into a deflection of duct 32 and thus runs beyond one of the two duct boundary contours 46, 47.

In the respective duct region KB, which is located between the intake line region ZB and the discharge line region AB and thus has neither the intake line IN nor the discharge line OUT, there are often alternating regions in the flow direction of the temperature control agent in which the distance A or the duct diameter or the duct width increases or decreases in the flow direction. Normally, that is, in the usual case, the cross-section through which flow can occur and the centerline can be determined using a standard approach. The duct diameter usually describes the smallest distance A between the two duct boundary contours 46, 47, and individual sections through the duct 32 are then defined by a tangential contact or by contact points of the circles K on the two duct boundary contours 46, 47. In other words, the standard method involves generating circles K that are tangent to both duct boundary contours 46, 47 at a single contact point. The center M of the respective circle K then forms a point on the centerline 37 of the duct 32.

In particular, the following special cases can occur in curves of the duct 32. If a radius of the outer duct boundary contour 46, 47 at the contact point of the circle K is smaller than the circle radius, and thus smaller than half of the duct diameter, the following scenarios can occur:

The following relationship can arise with a decreasing duct diameter in the flow direction. If the circles K are moved downstream, the distance between the center of the circle and the contact points with the two duct boundary contours 46, 47 is reduced. At the contact points, the circle K and the respective duct boundary contour 46, 47 touch each other tangentially, so that at the respective contact point, a circle circumference and the duct boundary contour 46, 47 run parallel to each other. Circles K with ever decreasing diameter are “pushed” in the flow direction into duct 32 until contact points with tangential contact are found on both sides. Potential further upstream or downstream non-tangential points of intersection of the duct boundary contours 46, 47 with the circle K are not taken into account. The contact points found in this way define a section through duct 32, which leads to the duct cross-section being searched for and, via its center point M, to a point on centerline 37. As soon as the circle K becomes so small that it “falls through” a bottleneck of duct 32 without coming into contact with both duct boundary contours 46, 47, a region with an increasing duct diameter in the flow direction is reached.

With a particularly small or narrow radius of the respective outer duct boundary contour 46, 47, the following relationship may arise: The radius of the outer curve of the duct boundary contour 46, 47 is smaller than the circle radius. In this case, a point of the outer duct boundary contour 46, 47 of the curve is selected to define the section that determines the duct cross- section through which the flow can pass and the centerline 37, and the orthogonal projection onto the inner duct boundary contour 46, 47 of the curve then represents the desired section that defines the duct cross-section through which the flow can pass and whose center point M results in a point of the centerline 37. As soon as a tangential contact is achieved again at the selected point, you can continue with the standard procedure described above, with tangential contact of the circles K to the duct boundary contours 46, 47.

The following relationship can arise with a duct diameter that increases in the flow direction. If the circles K are moved downstream, the distance between the center of the circle and the tangential contact points with the two duct boundary contours 46, 47 increases. The contact points define the distance A or the duct diameter of the cross-section that can be flowed through, and the center point M of the distance A or the duct diameter provides another point on the centerline 37. As soon as the district of K has reached a point where no further enlargement is possible, there is a region with a duct width that increases in the flow direction.

With a particularly small or narrow radius of the respective outer duct boundary contour 46, 47, the following relationship may arise: If the radius of the outer duct boundary contour 46, 47 is smaller than the circle radius, a point on the outer duct boundary contour 46, 47 is selected to define the cross-section and the orthogonal projection on the inner duct boundary contour 46, 47 represents the cross-section in question. As soon as a tangential contact is achieved again at the selected point, the standard procedure can be continued with a tangential contact of the circle K on both duct boundary contours 46, 47.

In the discharge line region AB, in which the discharge line OUT is located, circles K can be generated analogous to the intake line region ZB, centered on the discharge line OUT, which each have an intersection point S with both duct boundary contours 46, 47. Alternatively, the standard procedure for a duct region with a cross-section that decreases in the flow direction can also be used here.

For the centerline 37, the duct cross-section, i.e. the product of duct width and duct height, is the same from the centerline 37 to both duct boundary contours 46, 47 in each cross-section found. With a constant duct height, the centerline 37 lies exactly in the middle between the two duct boundary contours 46, 47 in the cross-sections.

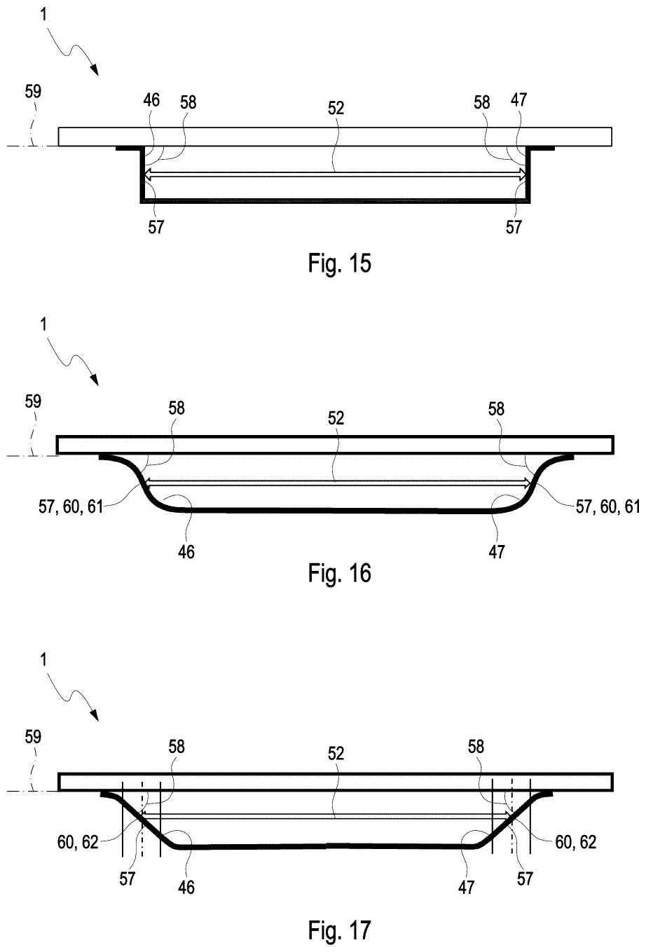

According to FIGS. 15 through 17, the distance 52 can be measured on the left duct boundary contour 46 and on the right duct boundary contour 47 with respect to an unspecified thickness direction or height direction of the heat exchanger plate 1, preferably in the center of a region 57 with the greatest inclination angle 58 with respect to a plate plane 59 in which the heat exchanger plate 1 extends. The design of the respective duct is shown in a highly simplified way in FIGS. 15 through 17. The height or thickness direction is perpendicular to the plate plane 59 and runs vertically in FIGS. 15 through 17. The plate plane 59 extends horizontally in FIGS. 15 through 17.

In the example of FIG. 15, the two duct boundary contours 46, 47 are configured straight and have an exemplary inclination angle 58 of 90° with respect to the plate plane 59. Other angles of inclination are also possible. In any case, for duct boundary contours 46, 47 that are straight in the Z height direction, the inclination to the plate plane 59 in the Z height direction along the duct boundary contour 46, 47 is constant, so that the distance measurement with respect to the Z height direction is made in the center of the respective duct boundary contour 46, 47. In the examples of FIGS. 16 and 17, the two duct boundary contours 46, 47 are curved in the Z-direction. With curved duct boundary contours 46, 47, the steepest point 60 of the respective duct boundary contour 46, 47 is used for the distance measurement. At this point 60, the respective duct boundary contour 46, 47 has the greatest angle of inclination 58 with respect to the plate plane 59. If this steepest point 60 is a point 61 of the respective duct boundary contour 46, 47, according to the example of FIG. 16, the distance measurement with respect to the height direction Z is carried out at this point 61. If, on the other hand, this steepest point 60 is, as in the example of FIG. 17, a straight region 62 of the respective duct boundary contour 46, 47 with a constant angle of inclination 58, the distance measurement with respect to the height direction Z is carried out in the center of this straight region 62.

If the respective region of the duct system has several flow paths through which the temperature control agent flows in parallel, the following procedure can be followed. The flow can be considered as a single duct from the intake line IN to the discharge line OUT, or as a number of ducts running partially or completely parallel. For parallel ducts, the flow length for each duct is determined as described above and the duct length is determined as the duct cross-section weighted mean value of the lengths of the individual ducts. In the case of bifurcations and unions, a common duct cross-section is determined for all sections by calculating the mean value of the length weighted with the individual cross-sections and by summing up the individual cross-sections. A certain length portion refers to these mean values in the region of parallel flow ducts and to the centerline of the duct in the region of a single duct.

According to FIG. 14, in an advantageous embodiment, it can also be provided that the duct system 7 has a distributing region VB having the intake line IN, which is designated at least in FIGS. 1 through 3, 5 through 7 and 14 and which has a distributing region length. In addition, the duct system 7 has a collecting region SB that has the discharge line OUT, which is designated at least in FIGS. 1 through 3, 5 through 7 and 14 and which has a collecting region length. Furthermore, the duct system 7 can form a contact region KB within the temperature control zone 30, which is only designated in FIG. 14 and which is configured on the plate surface 3 for heat-transferring coupling with the respective component 63 to be temperature-controlled and which has a contact region length that extends from the distributing region VB to the collecting region SB. The entry region 26 introduced above now extends within the contact region KB and connects to the distributing region VB. The exit region 27, which was introduced above, also extends within the contact region KB and connects to the collecting region SB. This means that the distributing region VB with the intake line IN and the collecting region SB with the discharge line OUT are outside the contact region KB, while the entry region 26, the distributing region 34 and the exit region 27 are within the contact region KB. The contact region KB can now be selected large enough to ensure that component 63, in particular the traction battery 64, can be fully contacted and fully temperature controlled.

In particular, it may be stipulated that the entry region length, the exit region length and the connecting region length each amount to ⅓ of the contact region length. It is also advantageous to have a configuration in which the distributing region length and the collecting region length each amount to a maximum of 15% of the total duct system length.

In another embodiment, the distributing region length and the collecting region length can each be 9.5% of the total duct system length 41. Alternatively, it may also be the case that the distributing region length and the collecting region length together amount to 19% of the total duct system length 41. In addition, it may be stipulated that the entry region length, the exit region length and the connecting region length each amount to 27% of the total duct system length 41. Alternatively, it may also be stipulated that the entry region length, the exit region length and the connecting region length together make up 81% of the total duct system length.

An arrangement of a traction battery 64 on a heat exchanger plate 1 of the type described above, according to FIG. 14, is characterized in that the traction battery 64 is arranged within the contact region KB on the plate surface 3 and is coupled to the heat exchanger plate 1 in a heat-transferring manner. The dimensions of the traction battery 64 can define the extent of the contact region KB within the duct system 7. In other words, the distributing region VB and the collecting region SB are both outside the traction battery 64, while the contact region KB is covered by the traction battery 64.

The arrangement 65 of the traction battery 64 on the heat exchanger plate 1 corresponds to a unit, also designated 65, of the traction battery 64 and the heat exchanger plate 1, in which the traction battery 65 is arranged within the contact region KB on the plate surface 3 and is coupled to the heat exchanger plate 1 in a heat-transferring manner.

The traction battery 64 can be arranged as a uniform assembly directly on the heat exchanger plate 1. The traction battery 64 usually has a large number of battery cells that are not shown in detail. In principle, the battery cells can be arranged directly on the heat exchanger plate 1. Likewise, it is conceivable that the traction battery 64 has several battery modules 66, each of which has several battery cells (not shown). In this case, the battery modules 66 can be arranged directly on the heat exchanger plate 1. FIG. 14 shows six battery modules 66.

1. A heat exchanger plate for temperature control of at least one of an electric component and an electronic component via a liquid temperature control agent, comprising:
a plate body having i) a plate surface for heat-transferring coupling with a component to be temperature controlled and ii) a peripheral plate edge;
the plate body including at least one temperature control zone disposed within the plate edge, the at least one temperature control zone including an intake line formed on the plate body with at least one intake line connection for supplying the temperature control agent, a discharge line formed on the plate body having at least one discharge line connection for draining the temperature control agent, and a duct system formed in the plate body for conducting the temperature control agent, the duct system fluidically connecting the intake line to the discharge line;
the duct system defining a main flow direction extending from the intake line to the discharge line;
the duct system having, with respect to the main flow direction, a left duct boundary contour and a right duct boundary contour, which delimit a cross-section of the duct system extending transverse to the main flow direction and through which the temperature control agent is flowable;
the duct system defining a left minimum distance extending from the intake line, along the left duct boundary contour, to the discharge line, and a right minimum distance extending from the intake line, along the right duct boundary contour, to the discharge line;
the duct system having a total duct system length extending from the intake line to the discharge line;
the duct system configured such that the total duct system length is 50% or less greater than at least one of i) a longer of the left minimum distance and the right minimum distance and ii) the left minimum distance and the right minimum distance when the left minimum distance and the right minimum distance are the same;
the duct system further having:
an entry region having an entry region length extending over 20% to 40% of the total duct system length;
an exit region having an exit region length extending over 20% to 40% of the total duct system length; and
a connecting region connecting the entry region to the exit region;
wherein a mean entry region cross-section through which the temperature control agent is flowable in the entry region is larger than a mean exit region cross-section through which the temperature control agent is flowable in the exit region.

2. The heat exchanger plate according to claim 1, wherein the total duct system length is equal to or less than at least one of:
the larger of the left minimum distance and the right minimum distance; and
the left minimum distance and the right minimum distance when the left minimum distance and the right minimum distance are equal.

3. The heat exchanger plate according to claim 1, wherein the total duct system length is smaller than at least one of:
the larger of the left minimum distance and the right minimum distance; and
the left minimum distance and the right minimum distance when the left minimum distance and the right minimum distance are the same.

4. The heat exchanger plate according to claim 1, wherein:
the duct system further has:
a distributing region with the intake line, which has a distributing region length; and
a collecting region with the discharge line, which has a collecting region length;
the duct system forms a contact region within the temperature control zone, the contact region configured on the plate surface for heat-transferring coupling with the component to be temperature-controlled and having a contact region length extending from the distributing region to the collecting region;
the entry region extends within the contact region and adjoins the distributing region; and
the exit region extends within the contact region and connects to the collecting region.

5. The heat exchanger plate according to claim 4, wherein the entry region length, the exit region length, and the collecting region length are each ⅓ of the contact region length.

6. The heat exchanger plate according to claim 4, wherein the distributing region length and the collecting region length each amount to 15% or less of the total duct system length.

7. The heat exchanger plate according to claim 4, wherein:
the distributing region length and the collecting region length at least one of i) each amount to 9.5% of the total duct system length and ii) together amount to 19% of the total duct system length; and
the entry region length, the exit region length, and a connecting region length at least one of i) each equal 27% of the total duct system length and ii) together equal 81% of the total duct system length.

8. The heat exchanger plate according to claim 1, wherein:
in the duct system in the main flow direction, a distance between the left duct boundary contour and the right duct boundary contour varies, the distance having a plurality of extrema;
the duct system further has, between the intake line and the discharge line, a plurality of duct sections that each extend in the main flow direction from an associated extremum of the plurality of extrema of the distance to a next extremum of the plurality of extrema of the distance;
at each extremum of the plurality of extremum of the distance, a straight line extending along the distance is perpendicular to the left duct boundary contour and perpendicular to the right duct boundary contour;
each of the plurality of duct sections has a respective section length measured along a centerline of the respective duct section;
the centerline is defined by a plurality of midpoints of a plurality of connecting straight lines, the plurality of connecting straight lines each connecting a point of the left duct boundary contour, which has a percentage length portion between two extrema of the plurality of extrema lying in the range from 0% to 100% on the left duct boundary contour, with a point of the right duct boundary contour, which has a percentage length portion between two extrema of the plurality of extrema on the right duct boundary contour that is equal to the percentage length portion of the left duct boundary contour; and
the total duct system length is equal to a sum of the section length of all successive duct sections of the plurality of duct sections from the intake line to the discharge line.

9. The heat exchanger plate according to claim 1, wherein:
the mean entry region cross-section is formed by an entry region volume, through which the temperature control agent is flowable in the entry region, relative to the entry region length; and
the mean exit region cross-section is formed by an exit region volume, through which the temperature control agent is flowable in the exit region, based on the exit region length.

10. The heat exchanger plate according to claim 8, wherein:
the entry region length is formed by a sum of the section length of all the plurality of duct sections disposed in the entry region; and
the exit region length is formed by a sum of the section length of all the plurality of duct sections disposed in the exit region.

11. The heat exchanger plate according to claim 1, wherein the mean entry region cross-section is at least 50% larger than the mean exit region cross-section.

12. The heat exchanger plate according to claim 11, wherein, the mean entry region cross-section is 70% to 600% larger than the mean exit region cross-section.

13. The heat exchanger plate according to claim 1, wherein a mean connecting region cross-section through which the temperature control agent is flowable in the connecting region is i) smaller than the mean entry region cross-section and ii) larger than the mean exit region cross-section.

14. The heat exchanger plate according to claim 13, wherein the mean cross-section of the connecting region is formed by a connecting region volume through which the temperature control agent is flowable in the connecting region, relative to a connecting region length extending from the entry region to the exit region.

15. The heat exchanger plate according to claim 8, wherein:
a mean connecting region cross-section through which the temperature control agent is flowable in the connecting region is i) smaller than the mean entry region cross-section and ii) larger than the mean exit region cross-section;
the mean cross-section of the connecting region is formed by a connecting region volume through which the temperature control agent is flowable in the connecting region, relative to a connecting region length extending from the entry region to the exit region; and
the connecting region length is formed by a sum of the section length of all the plurality of duct sections disposed in the connecting region.

16. The heat exchanger plate according to claim 1, wherein a heat transfer coefficient of the duct system is smaller in the entry region than in at least one of the exit region and the connecting region.

17. The heat exchanger plate according to claim 1, wherein:
the duct system includes a plurality of paths that each guide the temperature control agent from the intake line through a distributing duct to a connecting duct, from the connecting duct to a collecting duct, and from the collecting duct to the discharge line, the plurality of paths each having a path length;
each path of the plurality of paths the path length of which is less than 50% of the path length of a longest path of the plurality of paths forms a short path; and
a sum of a smallest cross-section of all short paths of the plurality of paths through which the temperature control agent is flowable is less than 40% of a sum of a smallest cross-section of all other paths of the plurality of paths through which the temperature control agent is flowable.

18. A use of a heat exchanger plate according to claim 1 for controlling a temperature of a plurality of battery cells of a traction battery of a battery-powered electric vehicle.

19. An arrangement, comprising a traction battery and a heat exchanger plate according to claim 4, wherein the traction battery is arranged on the heat exchanger plate within the contact region of the plate surface and is coupled to the heat exchanger plate in a heat-transferring manner.

20. The heat exchanger plate according to claim 12, wherein, the mean entry region cross-section is 100% to 400% larger than the mean exit region cross-section.
